(19) United States
(12) Patent Application Publication
(10) Pub. No.: US 2025/0133921 A1
(43) Pub. Date: Apr. 24, 2025

(54) DISPLAY DEVICE AND METHOD OF MANUFACTURING THE SAME

(71) Applicant: Samsung Display Co., LTD., Yongin-si (KR)

(72) Inventors: Chang Ho YI, Yongin-si (KR); Joo Sun YOON, Yongin-si (KR)

(73) Assignee: Samsung Display Co., LTD., Yongin-si (KR)

(21) Appl. No.: 18/763,499

(22) Filed: Jul. 3, 2024

(30) Foreign Application Priority Data
Oct. 20, 2023 (KR) 10-2023-0141321

(51) Int. Cl. H10K 59/124; H10K 59/12; H10K 59/121

(52) U.S. Cl. CPC H10K 59/124; H10K 59/1201; H10K 59/1213

(57) ABSTRACT

A display device according to an embodiment includes a substrate, a first transistor including a first active layer disposed on the substrate and including a first portion including a first channel region and a second portion and a third portion spaced apart from each other with the first portion disposed between the second portion and the third portion, and a first gate electrode disposed on the first portion of the first active layer, at least one first dummy gate electrode disposed on a part of at least one of the second portion or the third portion of the first active layer and spaced apart from the first gate electrode, and a first gate insulating layer disposed between the first active layer and each of the first gate electrode and the at least one first dummy gate electrode.

### CROSS-REFERENCE TO RELATED APPLICATION(S)

This application claims priority to and benefits of Korean Patent Application No. 10-2023-0141321 under 35 U.S.C. § 119, filed on Oct. 20, 2023, in the Korean Intellectual Property Office, the entire contents of which are incorporated herein by reference.

### BACKGROUND

### 1. Technical Field

Embodiments relate to a display device and a method of manufacturing the display device.

### 2. Description of the Related Art

The importance of display devices has steadily increased with the development of multimedia technology. Accordingly, various types of display devices such as a liquid crystal display device or a light emitting display device have been developed.

### SUMMARY

Embodiments provide a display device capable of making the operating characteristics of a transistor uniform and improving image quality, and a method of manufacturing the display device.

However, aspects of the disclosure are not restricted to the one set forth herein. The above and other aspects of the disclosure will become more apparent to one of ordinary skill in the art to which the disclosure pertains by referencing the detailed description of the disclosure given below.

According to an aspect of the disclosure, there is provided a display device including a substrate, a first transistor including a first active layer disposed on the substrate and including a first portion including a first channel region and a second portion and a third portion spaced apart from each other with the first portion disposed between the second portion and the third portion, and a first gate electrode disposed on the first portion of the first active layer, at least one first dummy gate electrode disposed on a part of at least one of the second portion or the third portion of the first active layer and spaced apart from the first gate electrode, and a first gate insulating layer disposed between the first active layer and each of the first gate electrode and the at least one first dummy gate electrode.

In an embodiment, the first gate insulating layer may include a first insulating pattern layer disposed between the first active layer and the first gate electrode and may expose a part of each of the second portion and the third portion of the first active layer.

In an embodiment, the first gate insulating layer may further include a second insulating pattern layer disposed between the at least one first dummy gate electrode and the first active layer.

In an embodiment, the first active layer may further include a first source region disposed in the second portion and disposed at a side of the first channel region, and a first drain region disposed in the third portion and disposed at another side of the first channel region, and the first gate electrode may cover at least the first channel region and may overlap a part of the first source region and a part of the first drain region by a first length in a longitudinal direction of the first active layer.

In an embodiment, the first dummy gate electrode may have a length less than or equal to the first length in the longitudinal direction of the first active layer.

In an embodiment, the first dummy gate electrode may have a length longer than the first length in the longitudinal direction of the first active layer, and the first active layer may further include at least one dummy channel region disposed in at least one of the second portion or the third portion and overlapping the first dummy gate electrode.

In an embodiment, the first dummy gate electrode may cover the dummy channel region and overlap a part of the first source region or a part of the first drain region around the dummy channel region.

In an embodiment, the dummy channel region may have a short channel such that a dummy transistor including the first dummy gate electrode and the dummy channel region may operate in a threshold voltage roll-off region.

In an embodiment, the display device may further include a pixel including a plurality of pixel transistors including the first transistor, and the dummy channel region may have a length shorter than a length of a channel region of each of the plurality of pixel transistors.

In an embodiment, the display device may further include an interlayer insulating layer disposed on the substrate, and covering the first active layer, the first gate insulating layer, the first gate electrode and the first dummy gate electrode, and the first transistor may further include at least one of a first source electrode disposed on the interlayer insulating layer and electrically connected to the first source region, or a first drain electrode disposed on the interlayer insulating layer and electrically connected to the first drain region.

In an embodiment, the display device may further include a power line electrically connected to the first dummy gate electrode and to which a gate-on voltage of the first transistor is applied.

In an embodiment, the display device may further include a pixel including a pixel circuit including the first transistor and a light emitting element connected to the pixel circuit, and the first transistor may be a driving transistor which controls a driving current flowing through the light emitting element in response to a voltage applied to the first gate electrode.

In an embodiment, the at least one first dummy gate electrode may include a plurality of first dummy gate electrodes, and the plurality of first dummy gate electrodes may be disposed at sides of the first gate electrode and disposed above each of the second portion and the third portion of the first active layer.

In an embodiment, the pixel circuit may further include a second transistor electrically connected to the first gate electrode, and the second transistor may include a second active layer disposed on the substrate and including a first portion including a second channel region, a second portion disposed at a side of the second channel region and including a second source region, and a third portion disposed at another side of the second channel region and including a second drain region, and a second gate electrode disposed on the first portion of the second active layer.

In an embodiment, the pixel may further include at least one second dummy gate electrode disposed on a part of at least one of the second portion or the third portion of the second active layer, and spaced apart from the second gate electrode, and a second gate insulating layer including insulating pattern layers disposed between the second active layer and each of the second gate electrode and the at least one second dummy gate electrode.

In an embodiment, the second gate insulating layer may expose a part of each of the second portion and the third portion of the second active layer, and the second gate electrode may cover at least the second channel region and overlap a part of each of the second source region and the second drain region around the second channel region.

In an embodiment, the at least one second dummy gate electrode may include a plurality of second dummy gate electrodes, and the plurality of second dummy gate electrodes may be disposed at sides of the second gate electrode and disposed above each of the second portion and the third portion of the second active layer.

In an embodiment, the second source region may be electrically connected to the first gate electrode, and the pixel may include a single second dummy gate electrode disposed only on the second portion of the second active layer.

In an embodiment, the first active layer and the second active layer may include an oxide semiconductor.

According to an aspect of the disclosure, there is provided a method of manufacturing a display device, including forming an active layer including an oxide semiconductor on a substrate, forming a gate insulating layer covering the active layer on the substrate, forming, on the gate insulating layer, a gate electrode and at least one dummy gate electrode which overlap different parts of the active layer and are spaced apart from each other, by etching the gate insulating layer, forming insulating pattern layers under each of the gate electrode and the at least one dummy gate electrode, and exposing a part of the active layer which does not overlap the gate electrode and the at least one dummy gate electrode, and forming an interlayer insulating layer covering the active layer, the insulating pattern layers, the gate electrode and the at least one dummy gate electrode.

A display device according to embodiments includes a transistor including an active layer and a gate electrode disposed on a part of the active layer, a dummy gate electrode disposed on the active layer and separated from the gate electrode, and a gate insulating layer disposed between each of the gate electrode and the dummy gate and the active layer. A method of manufacturing a display device according to embodiments includes forming the active layer, the gate electrode, the dummy gate electrode, and the gate insulating layer.

In accordance with the display device and the method of manufacturing the same according to embodiments, it is possible to reduce the amount of diffusion of oxygen vacancies diffused to a part of the active layer disposed under the gate electrode in the manufacturing process of the display device and/or the length of the region where the oxygen vacancies diffuses under the gate electrode. Therefore, the overlapping area between the source and/or drain regions of the transistor and the gate electrode may be reduced, and the parasitic capacitance of the transistor may be reduced. Accordingly, the operating characteristics of the transistor may become uniform and/or stable.

In some embodiments, the transistor may be a driving transistor of a pixel, or a switching transistor connected to the gate electrode of the driving transistor. In some embodiments, at least one dummy gate electrode may be formed above each of the active layers of at least one switching transistor and the driving transistor of the pixel. According to embodiments, it is possible to prevent, reduce, or minimize image stains due to the luminance variation of the pixels, and to improve the image quality of the display device.

However, effects according to the embodiments of the disclosure are not limited to those examples above and various other effects are incorporated herein.

### BRIEF DESCRIPTION OF THE DRAWINGS

The above and other aspects and features of the disclosure will become more apparent by describing in detail embodiments thereof with reference to the attached drawings, in which:

FIG. 1 is a schematic plan view illustrating a display device according to an embodiment;

FIG. 2 is a schematic plan view illustrating a display panel of FIG. 1;

FIG. 3 is a schematic diagram of an equivalent circuit of a pixel according to an embodiment;

FIG. 4 is a schematic diagram of an equivalent circuit of the pixel according to an embodiment;

FIG. 5 is a schematic plan view showing a pixel transistor and a dummy gate electrode according to an embodiment;

FIG. 6 is a schematic cross-sectional view illustrating the display panel according to an embodiment;

FIG. 7 is a schematic cross-sectional view illustrating the display panel according to an embodiment;

FIG. 8 is a schematic plan view showing the pixel transistor and the dummy gate electrode according to an embodiment;

FIG. 9 is a schematic cross-sectional view illustrating the display panel according to an embodiment;

FIG. 10 is a schematic cross-sectional view illustrating the display panel according to an embodiment;

FIGS. 11, 12, 13, 14, 15, 16, 17, and 18 are schematic cross-sectional views illustrating a method of manufacturing the display device according to an embodiment;

FIG. 19 is a schematic cross-sectional view illustrating the display panel according to one embodiment; and

FIG. 20 is a schematic cross-sectional view illustrating the display panel according to one embodiment.

### DETAILED DESCRIPTION OF THE EMBODIMENTS

In the following description, for the purposes of explanation, numerous specific details are set forth in order to provide a thorough understanding of various embodiments or implementations of the invention. As used herein, “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element or a layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the axis of the first direction D1, the axis of the second direction D2, and the axis of the third direction D3 are not limited to three axes of a rectangular coordinate system, such as the X, Y, and Z-axes, and may be interpreted in a broader sense. For example, the axis of the first direction D1, the axis of the second direction D2, and the axis of the third direction D3 may be perpendicular to one another, or may represent different directions that are not perpendicular to one another. For the purposes of this disclosure, “at least one of A and B” may be understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the invention. Further, the blocks, units, and/or modules of some embodiments may be physically combined into more complex blocks, units, and/or modules without departing from the scope of the invention.

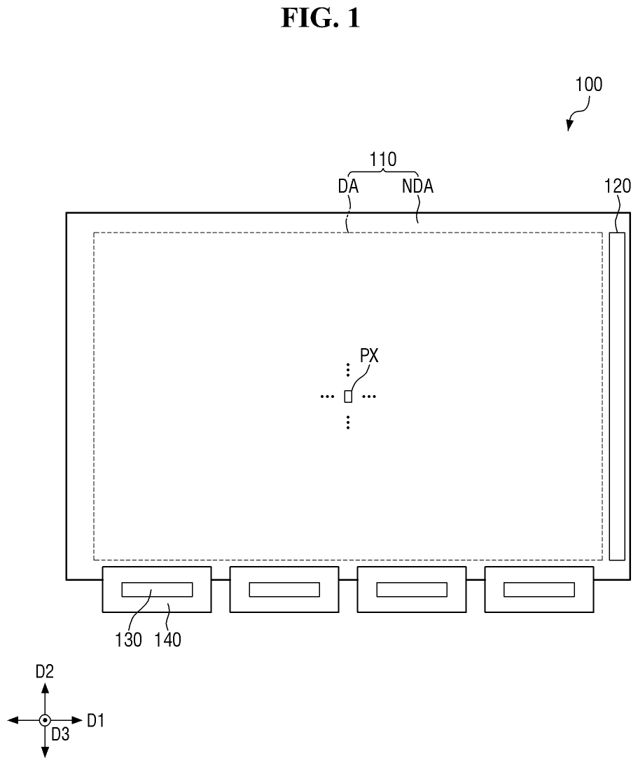

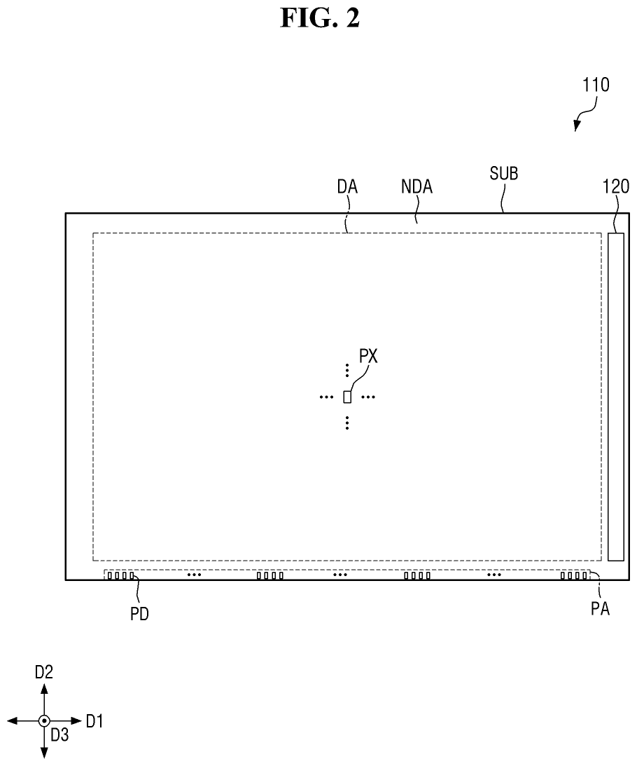

FIG. 1 is a schematic plan view illustrating a display device 100 according to an embodiment. FIG. 2 is a schematic plan view illustrating a display panel 110 of FIG. 1.

Referring to FIGS. 1 and 2, the display device 100 may be a device for displaying a moving image or a still image. The display device 100 may be used as a display screen of various devices, such as a television, a laptop computer, a monitor, a billboard and an Internet-of-Things (IoT) device, as well as portable electronic devices such as a mobile phone, a smartphone, a tablet personal computer (PC), a smart watch, a watch phone, a mobile communication terminal, an electronic notebook, an electronic book, a portable multimedia player (PMP), a navigation device and an ultra-mobile PC (UMPC). These are examples, and the display device 100 may be applicable to various other types of electronic devices.

In an embodiment, the display device 100 may be a light emitting display device such as an organic light emitting display including an organic light emitting diode, a quantum dot light emitting display including a quantum dot light emitting layer, an inorganic light emitting display including an inorganic semiconductor, or an ultra-small light emitting display using an ultra-small light emitting diode such as a micro light emitting diode (micro LED) or a nano light emitting diode (nano LED), but embodiments are not limited thereto. For example, the display device 100 may be another type of display device other than a light emitting display device. In the following, embodiments in which the display device 100 is an organic light emitting display device will be disclosed.

The display device 100 may include the display panel 110 including pixels PX, and a first driver 120 and a second driver 130 that supplies driving signals to the pixels PX. The display device 100 may further include additional components. For example, the display device 100 may further include a power supply unit for supplying power voltages to the pixels PX, the first driver 120, and the second driver 130, and a timing controller for controlling the operations of the first driver 120 and the second driver 130.

The display panel 110 may include a display area DA and a non-display area NDA (also referred to as a “bezel area”). The display area DA may be an area including the pixels PX to display an image. The non-display area NDA may be an area other than the display area DA, and an image may not be displayed in the non-display area NDA. In an embodiment, the non-display area NDA may be positioned around the display area DA and may surround the display area DA.

In FIGS. 1 and 2, a first direction D1, a second direction D2, and a third direction D3 are defined. In an embodiment, the first direction D1 and the second direction D2 may be perpendicular to each other, the first direction D1 and the third direction D3 may be perpendicular to each other, and the second direction D2 and the third direction D3 may be perpendicular to each other. For example, the first direction D1 may be the horizontal direction (for example, a row direction or X-axis direction) of the display panel 110, and the second direction D2 may be the vertical direction (for example, a column direction or Y-axis direction) of the display panel 110. The third direction D3 may be the thickness direction (for example, a height direction or Z-axis direction) of the display panel 110.

In an embodiment, the display panel 110 may have a rectangular shape in plan view. For example, the display panel 110 may include two first sides extending in the first direction D1 and two second sides extending in the second direction D2 intersecting the first direction D1. Although FIGS. 1 and 2 illustrate the display panel 110 in which the first side in the horizontal direction is longer than the second side in the vertical direction, the shape of the display panel 110 is not limited thereto. For example, the display panel 110 may have a shape in which the second side in the vertical direction is longer than the first side in the horizontal direction, or the lengths of the first side and the second side are substantially the same.

In an embodiment, the display panel 110 may include an angled corner at a portion where the first side and the second side meet, but embodiments are not limited thereto. For example, the display panel 110 may include a rounded corner at a portion where the first side and the second side meet.

The planar shape of the display panel 110 is not limited to the illustrated rectangular shape, and it may be applied in other shapes. For example, the display panel 110 may have a square shape, a non-quadrilateral polygonal shape, a circular shape, an elliptical shape, an atypical shape, or another shape in plan view.

In an embodiment, the display panel 110 may be substantially flat on the plane defined by the first direction D1 and the second direction D2, and may have a uniform thickness in the third direction D3. In another embodiment, the display panel 110 may be provided in a three-dimensional shape having a curved surface or the like.

The display panel 110 may be provided as a panel having rigid characteristics so as not to be substantially deformed, or as a panel having flexible characteristics that are transformed to be at least partially folded, bent, or rolled. The display panel 110 may be provided to the display device 100 without bending, or may be provided to the display device 100 while being partially bent.

The display panel 110 may include a substrate SUB and pixels PX disposed on the substrate SUB. The pixels PX may be disposed in the display area DA on the substrate SUB.

The substrate SUB, which is a base member for manufacturing or providing the display panel 110, may form the base surface of the display panel 110. The substrate SUB may include the display area DA and the non-display area NDA positioned around the display area DA.

The display area DA may have various shapes according to embodiments. For example, the display area DA may have a quadrilateral shape, a non-quadrilateral polygonal shape, a circular shape, an elliptical shape, an atypical shape, or another shape. In an embodiment, the display area DA may have a shape corresponding to the shape of the display panel 110, but embodiments are not limited thereto.

The display area DA may include pixel areas where the pixels PX are provided and/or disposed. For example, each pixel PX may be disposed in each pixel area positioned in the display area DA. In an embodiment, the display device 100 may be a light emitting display device, and each pixel PX may include a light emitting element positioned in each emission area and a pixel circuit connected to the light emitting element. In describing embodiments, the term “connect” may include electrical connection and/or physical connection.

Each pixel area may include an emission area where the light emitting element of the corresponding pixel is positioned and where the pixel emits light, and a pixel circuit area where circuit elements of the pixel circuit of the corresponding pixel are positioned. The emission area and the pixel circuit area of each pixel PX may overlap each other, but embodiments are not limited thereto.

The pixels PX may be arranged in the display area DA. The arrangement type of the pixels PX may be variously changed according to embodiments.

The non-display area NDA may include a pad area PA where pads PD are disposed, and may selectively further include a driving circuit area positioned on at least one side of the display area DA. At least one driver, the pads PD, and/or wires may be disposed in the non-display area NDA.

At least one driver for driving the pixels PX, or a part of the driver may be disposed in the driving circuit area. For example, the circuit elements of the first driver 120 may be disposed in the driving circuit area on the substrate SUB. In an embodiment, the circuit elements of the first driver 120 may be formed in the display panel 110 together with the pixels PX.

The pads PD may be disposed in the pad area PA. At least one circuit board 140 may be disposed and/or bonded on the pad area PA. In an embodiment, circuit boards 140 connected to different pads PD may be disposed on the pad area PA. The pads PD may include signal pads and power pads for transmitting driving signals and power voltages required for driving the pixels PX and/or the first driver 120 into the display panel 110.

The first driver 120 and the second driver 130 may generate driving signals for controlling operation timing, luminance, and the like of the pixels PX, and may supply the generated driving signals to the pixels PX. For example, the first driver 120 may be a gate driver including a scan driver, and may be connected to the pixels PX through respective gate lines. The first driver 120 may supply respective gate signals (e.g., driving signals for controlling the operation timing of the pixels PX) to the pixels PX. The second driver 130 may be a data driver including source driving circuits, and may be connected to the pixels PX through respective data lines. The second driver 130 may supply respective data signals to the pixels PX.

In an embodiment, at least one first driver of the first driver 120 or the second driver 130 (or a part of the at least one first driver) may be embedded in the display panel 110. For example, the first driver 120 may be disposed on the substrate SUB of the display panel 110 and may be disposed and/or formed in the non-display area NDA.

Although FIG. 1 illustrates that the first driver 120 is formed on a side of the display area DA (for example, in the non-display area NDA on the right side of the display area DA), but the embodiments are not limited thereto. For example, the first driver 120 may be positioned only on another side (e.g., the non-display area NDA on the left side of the display area DA) of the display area DA, or may be positioned on sides (e.g., opposite sides) (e.g., the non-display area NDA on the left side and right side of the display area DA) of the display area DA. In another example, a part of the first driver 120 may be positioned in the non-display area NDA, and another part of the first driver 120 may be positioned in a non-emission area (e.g., area between the emission areas of the pixels PX) in the display area DA.

In an embodiment, the other driver of the first driver 120 and the second driver 130 (or a part of the other driver) may be disposed or formed outside the display panel 110 to be electrically connected to the display panel 110. For example, the second driver 130 may be implemented as integrated circuit chips, and may be disposed on the circuit boards 140 electrically connected to the pixels PX of the display panel 110. In another example, the second driver 130 may be implemented as at least one integrated circuit chip and mounted on the non-display area NDA of the display panel 110.

The circuit board 140 may be connected to the display panel 110 through the pads PD. In an embodiment, the circuit board 140 may be a flexible film such as a flexible printed circuit board (FPCB), a printed circuit board (PCB), or a chip on film (COF), but embodiments are not limited thereto. The circuit board 140 may be connected to the timing controller and/or the power supply unit through another circuit board, connector, or the like.

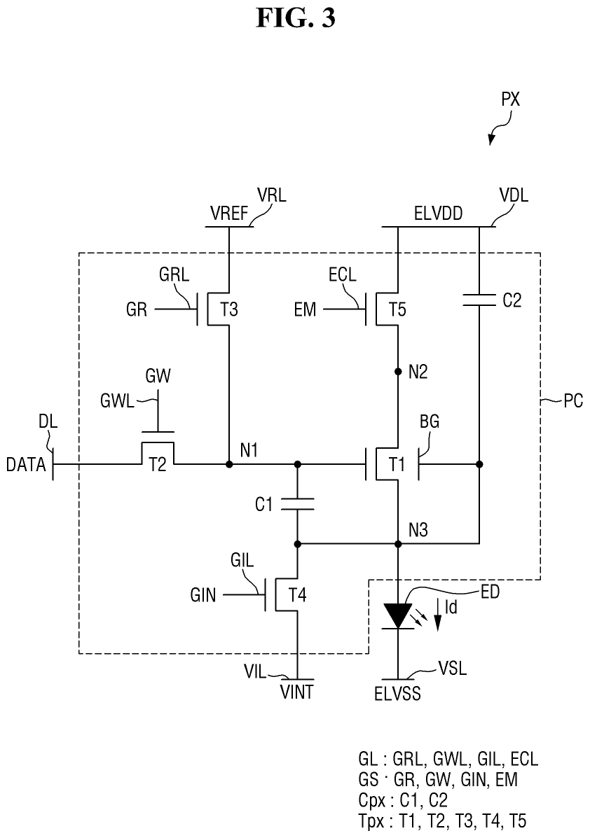

FIG. 3 is a schematic diagram of an equivalent circuit of the pixel PX according to an embodiment. The pixel PX of FIG. 3 is an example, and the structure or type of the pixel PX may be variously changed according to embodiments.

Referring to FIG. 3 in addition to FIGS. 1 and 2, the pixel PX may include a light emitting element ED, and a pixel circuit PC connected to the light emitting element ED. The light emitting element ED may be a light source of the pixel PX, and it may be, for example, an organic light emitting diode, but embodiments are not limited thereto. The pixel circuit PC may control the emission timing and the luminance of the light emitting element ED.

The pixel circuit PC may include pixel transistors Tpx and at least one pixel capacitor Cpx. For example, the pixel circuit PC may include first to fifth transistors T1 to T5, and first and second capacitors C1 and C2. The structure of the pixel circuit PC or the types of the circuit elements of the pixel circuit PC may be changed in various ways according to embodiments. Although FIG. 3 illustrates an embodiment in which the pixel transistors Tpx are all N-type transistors, the types of pixel transistors Tpx are not limited thereto. For example, at least one pixel transistor Tpx may be formed as a P-type transistor.

The pixel circuit PC may supply a driving current Id to the light emitting element ED in response to the driving signals supplied from the first driver 120 and the second driver 130. For example, the pixel circuit PC may supply the driving current Id to the light emitting element ED in response to respective gate signals GS supplied from the first driver 120 through respective gate lines GL and a data signal DATA supplied from the second driver 130 through a data line DL.

The first transistor T1 may be a driving transistor of the pixel PX whose magnitude (or amount) of drain-source current (e.g., the driving current Id) is determined according to the gate-source voltage. The second, third, fourth, and fifth transistors T2, T3, T4, and T5 may be switching transistors that are turned on or off in response to respective gate-source voltages. According to the type (for example, P-type or N-type) and/or operating conditions of each of the first to fifth transistors T1 to T5, a first electrode of each of the first to fifth transistors T1 to T5 may be a drain electrode (or a drain region), or a source electrode (or a source region), and a second electrode thereof may be an electrode different from the first electrode. For example, in case that the first electrode is a drain electrode, the second electrode may be a source electrode.

The pixel PX may be connected to a first gate line GWL that transmits the first gate signal GW (e.g., a scan signal), a second gate line GIL that transmits a second gate signal GIN, a third gate line GRL that transmits a third gate signal GR, an emission control line ECL that transmits an emission control signal EM, and the data line DL that transmits the data signal DATA. Further, the pixel PX may be connected to a first power line VDL that transmits a first pixel voltage ELVDD (also referred to as “first pixel power voltage”), and a second power line VSL that transmits a second pixel voltage ELVSS (also referred to as “second pixel power voltage”). In an embodiment, the pixel PX may be further connected to an initialization power line VIL that transmits an initialization voltage VINT (also referred to as “third pixel power voltage”), and a reference power line VRL that transmits a reference voltage VREF (also referred to as “fourth pixel power voltage”).

In an embodiment, the first to fifth transistors T1 to T5 may be positioned in each pixel area, and may be oxide transistors (also referred to as “oxide semiconductor transistors”) including an oxide semiconductor (e.g., an oxide semiconductor material). For example, an active layer including a channel region of each of the first to fifth transistors T1 to T5 may be formed of the oxide semiconductor. However, the embodiments are not limited thereto. For example, at least one pixel transistor Tpx may be formed of a semiconductor material (for example, amorphous silicon or polysilicon) other than an oxide semiconductor.

The oxide semiconductor may have high carrier mobility and a low leakage current, so that a considerable voltage drop may not occur although the driving time of the oxide transistor increases. For example, the pixel PX including an oxide transistor may be driven at a low frequency because the change in the luminance and/or the color of an image due to a voltage drop is not significant in case that it is driven at a low frequency. In the case of the display device 100 in which the first to fifth transistors T1 to T5 include an oxide semiconductor, the leakage current of the pixel PX may be reduced or prevented and the power consumption may be reduced.

The oxide semiconductor may be sensitive to light, so that the amount of current or the like may be changed due to external light. In an embodiment, a light blocking pattern layer or a lower electrode (e.g., a bottom gate electrode) may be disposed under the active layer included in at least one pixel transistor Tpx to block external light. Accordingly, the operating characteristics of the pixel transistor Tpx may become stable.

The first transistor T1 (also referred to as “first pixel transistor”) may include a gate electrode connected to a first node N1, a first electrode (for example, a drain electrode) connected to a second node N2, and a second electrode (for example, a source electrode) connected to a third node N3. The first electrode of the first transistor T1 may be connected to the first power line VDL via the fifth transistor T5, and the second electrode of the first transistor T1 may be connected to the light emitting element ED. The first transistor T1 may function as a driving transistor of the pixel PX, and may control the magnitude (for example, the amount of current) of the driving current Id flowing through the light emitting element ED in response to the data signal DATA transmitted to the first node N1.

In an embodiment, the first transistor T1 may further include a bottom gate electrode BG (e.g., the back-gate electrode of the first transistor T1) connected to the third node N3. In case that the first transistor T1 is formed as a transistor having a double gate structure (e.g., a double gate electrode having a source-sync structure) by connecting the bottom gate electrode BG of the first transistor T1 to the third node N3, the operating characteristics of the first transistor T1 may be improved.

The second transistor T2 (also referred to as “second pixel transistor”) may include a gate electrode connected to the first gate line GWL, a first electrode connected to the data line DL, and a second electrode connected to the first node N1. The second transistor T2 may be turned on by the first gate signal GW (for example, the gate-on voltage of the first gate signal GW) transmitted to the first gate line GWL to connect the data line DL and the first node N1. Accordingly, the data signal DATA transmitted through the data line DL may be transferred to the first node N1.

The third transistor T3 (also referred to as “third pixel transistor”) may include a gate electrode connected to the third gate line GRL, a first electrode connected to the reference power line VRL, and a second electrode connected to the first node N1. The third transistor T3 may be turned on by the third gate signal GR transmitted through the third gate line GRL and transmit the reference voltage VREF transmitted to the reference power line VRL to the first node N1.

The fourth transistor T4 (also referred to as “fourth pixel transistor”) may include a gate electrode connected to the second gate line GIL, a first electrode connected to the third node N3, and a second electrode connected to the initialization power line VIL. The fourth transistor T4 may be turned on by the second gate signal GIN transmitted through the second gate line GIL and transmit the initialization voltage VINT transmitted to the initialization power line VIL to the third node N3.

The fifth transistor T5 (also referred to as “fifth pixel transistor”) may include a gate electrode connected to the emission control line ECL, a first electrode connected to the first power line VDL, and a second electrode connected to the second node N2 (or the first electrode of the first transistor T1). The fifth transistor T5 may be turned on by the emission control signal EM (for example, the gate-on voltage of the emission control signal EM) transmitted to the emission control line ECL to control the emission timing of the pixel PX.

The first capacitor C1 may be connected between the first node N1 and the third node N3. For example, the first capacitor C1 may be connected between the second electrode and the gate electrode of the first transistor T1. The first capacitor C1 may be a storage capacitor of the pixel PX, and may store a threshold voltage of the first transistor T1 and a voltage corresponding to the data signal DATA (e.g., a data voltage).

The second capacitor C2 may be connected between the first power line VDL and the third node N3. In an embodiment, the capacity of the second capacitor C2 may be smaller than that of the first capacitor C1.

The light emitting element ED may be connected between the third node N3 and the second power line VSL. For example, the light emitting element ED may include a first electrode (e.g., an anode electrode) connected to the third node N3, a second electrode (e.g., a cathode electrode) facing the first electrode and connected to the second power line VSL, and a light emitting layer interposed between the first electrode and the second electrode. In an embodiment, the first electrode of the light emitting element ED may be an individual electrode individually provided in each pixel PX, and the second electrode of the light emitting element ED may be a common electrode shared by pixels PX. The light emitting element ED may emit light with a luminance corresponding to the driving current Id during a time period in which the driving current Id is supplied from the pixel circuit PC.

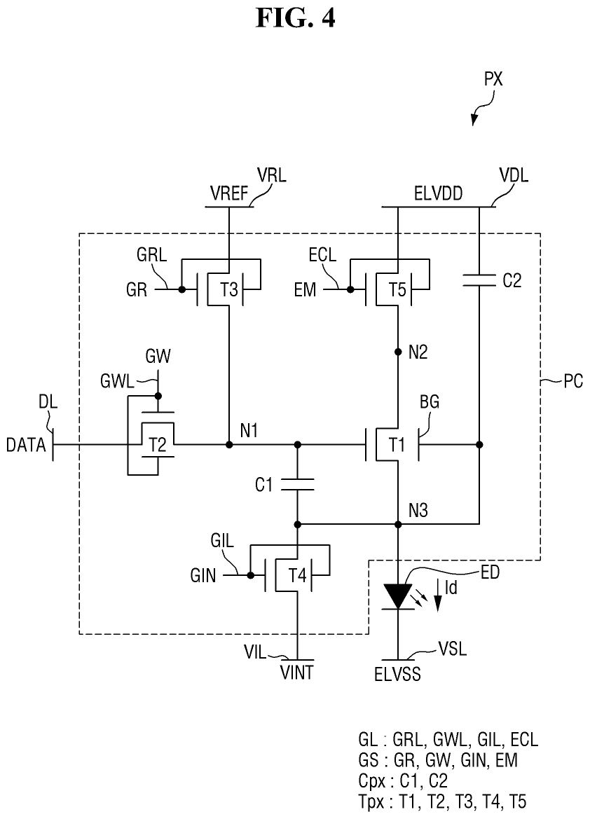

FIG. 4 is a schematic diagram of an equivalent circuit of the pixel PX according to an embodiment. For example, FIG. 4 shows an additional embodiment related to switching transistors among the pixel transistors Tpx of FIG. 3.

Referring to FIG. 4 in addition to FIGS. 1 to 3, at least one of the switching transistors provided in the pixel PX may include the bottom gate electrode BG (or the back-gate electrode) facing the gate electrode GE (e.g., a top gate electrode) with the active layer interposed between the bottom gate electrode BG and the gate electrode GE. For example, at least one of the second, third, fourth, and fifth transistors T2, T3, T4, and T5 may include the bottom gate electrode BG.

FIG. 4 shows an embodiment in which the bottom gate electrodes BG are provided in all the pixel transistors Tpx, and only the bottom gate electrode BG provided in a pixel transistor Tpx (e.g., the first transistor T1) is denoted by a notation. However, the embodiments are not limited thereto. For example, at least one pixel transistor Tpx may not include the bottom gate electrode BG, and/or may not be formed as a double gate transistor having a gate-sync or source-sync structure.

In an embodiment, the second, third, fourth, and fifth transistors T2, T3, T4, and T5 may include the respective bottom gate electrodes BG connected to the respective gate electrodes. For example, each of the second, third, fourth, and fifth transistors T2, T3, T4, and T5 may be formed as a double gate transistor having a gate-sink structure.

By providing the respective bottom gate electrodes BG in the second, third, fourth, and fifth transistors T2, T3, T4, and T5, it is possible to prevent or reduce the change in the amount of current of the second, third, fourth, and fifth transistors T2, T3, T4, and T5. Further, in case that the respective bottom gate electrodes BG of the second, third, fourth, and fifth transistors T2, T3, T4, and T5 are connected to the respective gate electrodes of the second, third, fourth, and fifth transistors T2, T3, T4, and T5, the operating characteristics (e.g., switching characteristics) of the second, third, fourth, and fifth transistors T2, T3, T4, and T5 may be improved and/or stabilized. For example, since at least one switching transistor is formed in a double gate structure of a gate-sink structure, it is possible to improve the off characteristics and the switching speed of the switching transistor, ensure an additional voltage tolerance range, lower a leakage current, and improve voltage stability. For example, since a small-sized switching transistor formed of an oxide transistor with a short channel length is formed in a double gate structure of a gate-sink structure, the operating characteristics of the switching transistor may be improved.

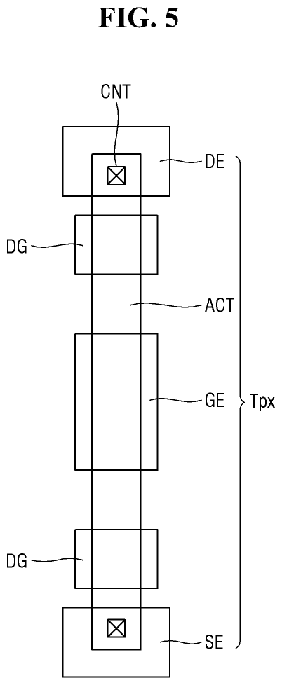

FIG. 5 is a schematic plan view showing the pixel transistor Tpx and a dummy gate electrode DG according to an embodiment. FIG. 5 shows a schematic planar shape of a pixel transistor Tpx representing the pixel transistors Tpx, and the shape and/or size of each pixel transistor Tpx may be variously changed according to embodiments.

Referring to FIG. 5 in addition to FIGS. 1 to 4, the pixel transistor Tpx may include an active layer ACT and a gate electrode GE disposed on a part of the active layer ACT. In an embodiment, the gate electrode GE may be the top gate electrode disposed on the active layer ACT, and a gate insulating layer may be disposed between the active layer ACT and the gate electrode GE.

In an embodiment, the pixel transistor Tpx may further include a source electrode SE and a drain electrode DE that are disposed on different parts (e.g., opposite parts) of the active layer ACT and connected to different parts (e.g., a part including a source region and a part including a drain region) of the active layer ACT through respective contact holes CNT. In FIG. 5, only one contact hole CNT may be denoted by a notation.

In an embodiment, at least one of the pixel transistors Tpx provided in the pixel PX may not include a separate source electrode SE and/or a separate drain electrode DE. For example, the source region and/or the drain region included in the active layer ACT of the at least one pixel transistor Tpx may be connected (e.g., directly connected) to another circuit element, wire, and/or conductive pattern layer.

In an embodiment, at least one pixel transistor Tpx may further include the bottom gate electrode BG, as in the embodiment of FIG. 3 or FIG. 4. For example, at least one pixel transistor Tpx may further include the bottom gate electrode BG that is disposed under the active layer ACT and faces the gate electrode GE with the active layer ACT interposed between the bottom gate electrode BG and the gate electrode GE.

At least one dummy gate electrode DG separated from the gate electrode GE may be disposed on the active layer ACT of at least one pixel transistor Tpx. For example, two dummy gate electrodes DG disposed on different parts (e.g., separated parts) of the active layer ACT and spaced apart from the gate electrode GE may be disposed on sides (e.g., opposite sides) of the gate electrode GE of at least one pixel transistor Tpx including the first transistor T1.

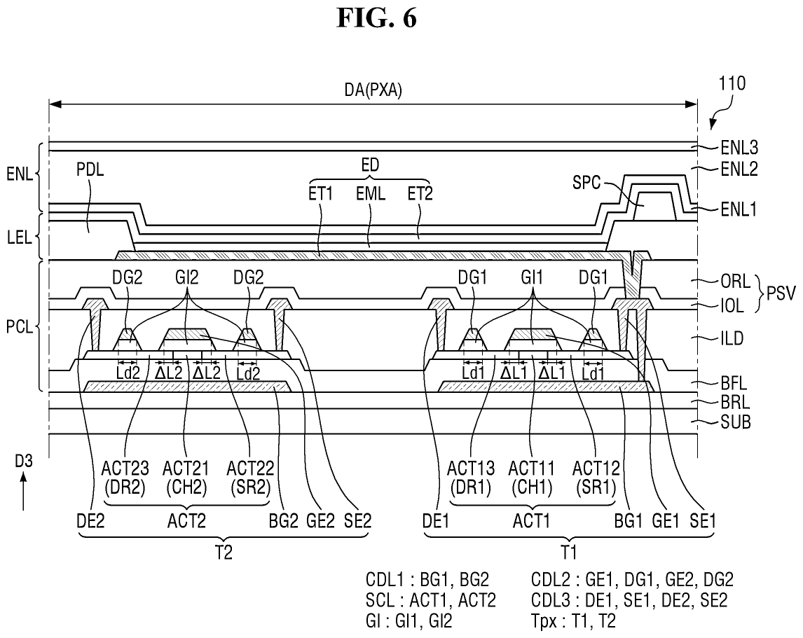

FIG. 6 is a schematic cross-sectional view illustrating the display panel 110 according to an embodiment. For example, FIG. 6 shows a part of the display area DA of the display panel 110.

FIG. 6 illustrates the first transistor T1 and the second transistor T2 disposed in a pixel area PXA as an example of circuit elements that are provided or disposed in a panel circuit layer PCL of the display panel 110. FIGS. 5 and 6 show a light emitting display panel including the light emitting element ED (for example, an organic light emitting diode) as an example of the display panel 110 to which embodiments may be applied. However, the type and/or structure of the display panel 110 are not limited thereto. For example, the display panel 110 may include a light emitting element of another type and/or structure, or may be a display panel of another type and/or structure other than the light emitting display panel.

Referring to FIG. 6 in addition to FIGS. 1 to 5, the display panel 110 may include the substrate SUB (also referred to as “base member” or “base layer”), the panel circuit layer PCL, a light emitting element layer LEL, and an encapsulation layer ENL. The panel circuit layer PCL, the light emitting element layer LEL, and the encapsulation layer ENL may be disposed or provided to overlap each other on the substrate SUB. In an embodiment, the panel circuit layer PCL, the light emitting element layer LEL, and the encapsulation layer ENL may be sequentially arranged or formed on the substrate SUB along the third direction D3.

In an embodiment, the display panel 110 may further include additional elements provided above and/or under the encapsulation layer ENL. For example, the display panel 110 may further include at least one of a sensor layer (for example, a touch sensor layer), an optical layer (for example, a color filter layer and/or a wavelength conversion layer), or a passivation layer (for example, a passivation film, an insulating layer, an upper substrate, and/or a window). Each of the sensor layer, the optical layer, and/or the passivation layer may be provided above the encapsulation layer ENL or may be provided between the light emitting element layer LEL and the encapsulation layer ENL.

The substrate SUB, which is a base member for forming the display panel 110, may be a substrate (or film) having rigid or flexible characteristics. In an embodiment, the substrate SUB may be a substrate including an insulating material such as glass or the like and having rigid characteristics, and may not be bent. In another embodiment, the substrate SUB may be a flexible substrate that includes polyimide or another insulating material and may be transformed to be bent, folded, or rolled, and may or may not be bent. The type and/or material of the substrate SUB may change according to embodiments.

The substrate SUB may include at least the display area DA. In an embodiment, the display area DA may include the pixel areas PXA corresponding to each of the pixels PX. For example, in the display area DA, the respective pixel areas PXA in which each of the pixels PX is disposed may be defined.

In an embodiment, a barrier layer BRL may be provided on the substrate SUB. For example, the display panel 110 may further include the barrier layer BRL disposed between the substrate SUB and the panel circuit layer PCL. In another embodiment, the display panel 110 may not include the barrier layer BRL, and the panel circuit layer PCL may be disposed (e.g., directly disposed) on the substrate SUB.

The barrier layer BRL may include at least one inorganic insulating layer including an inorganic insulating material (e.g., silicon nitride, silicon oxide, silicon oxynitride, titanium oxide, aluminum oxide, or another inorganic insulating material). The barrier layer BRL may protect the pixels PX from moisture permeating through the substrate SUB that is susceptible to moisture permeation. The material of the barrier layer BRL may be variously changed according to embodiments.

The panel circuit layer PCL may be disposed on a surface of the substrate SUB where the barrier layer BRL is provided. The panel circuit layer PCL may include circuit elements including the pixel transistors Tpx and the pixel capacitors Cpx, and wires (e.g., signal lines and power lines).

The panel circuit layer PCL may further include insulating layers disposed on the substrate SUB. For example, the panel circuit layer PCL may include a buffer layer BFL (also referred to as “first insulating layer”), a gate insulating layer GI (also referred to as “second insulating layer”), an interlayer insulating layer ILD (also referred to as “third insulating layer”), and a passivation layer PSV (also referred to as “fourth insulating layer”) that are sequentially disposed on the substrate SUB along the third direction D3. In an embodiment, the buffer layer BFL, the interlayer insulating layer ILD, and the passivation layer PSV may be formed in the entire display area DA, and the gate insulating layer GI may be formed of insulating pattern layers disposed on a part of each of the active layers ACT of the pixel transistors Tpx.

In an embodiment, the passivation layer PSV may have a multilayer structure including an inorganic layer (for example, an inorganic insulating layer) and an organic layer (for example, an organic insulating layer). For example, the passivation layer PSV may include an inorganic layer IOL and an organic layer ORL sequentially disposed on the interlayer insulating layer ILD.

In an embodiment, the display panel 110 may further include an additional conductive layer and/or an additional passivation layer. For example, the display panel 110 may further include at least one fourth conductive layer provided on the passivation layer PSV, and at least one insulating layer that covers the fourth conductive layer. In an embodiment in which the display panel 110 further includes the fourth conductive layer, at least one wiring and/or bridge pattern layer (for example, bridge pattern layer connected between a first source electrode SE1 of the first transistor T1 and a first electrode ET1 of the light emitting element ED) or the like may be provided in (or formed as) the fourth conductive layer.

In an embodiment, each of the buffer layer BFL, the gate insulating layer GI, the interlayer insulating layer ILD, and the inorganic layer IOL may include at least one inorganic insulating layer including an inorganic insulating material (e.g., silicon nitride, silicon oxide, silicon oxynitride, titanium oxide, aluminum oxide, or another inorganic insulating material).

The organic layer ORL may include at least one organic insulating layer including an organic insulating material (e.g., acryl resin, epoxy resin, phenolic resin, polyamide resin, polyimide resin, or other organic insulating materials). The surface (for example, the top surface) of the organic layer ORL may be substantially flat.

The pixel transistors Tpx may be included in the pixel circuit PC of each pixel PX, and may be positioned in the display area DA. For example, the first transistor T1 and the second transistor T2 provided to each of the pixels PX may be disposed in each of the pixel areas PXA in which the corresponding pixel PX is positioned. Further, at least another pixel transistor Tpx and/or at least one pixel capacitor Cpx may be further disposed in each pixel area PXA.

In an embodiment, at least one pixel transistor Tpx may include the bottom gate electrode BG. For example, the first transistor T1 may include a first bottom gate electrode BG1, and the second transistor T2 may include a second bottom gate electrode BG2. In an embodiment, the first bottom gate electrode BG1 and the second bottom gate electrode BG2 may be provided in the same layer (e.g., a first conductive layer CDL1) within the panel circuit layer PCL.

The first transistor T1 may include the first bottom gate electrode BG1 disposed on the substrate SUB, a first active layer ACT1 (also referred to as “first active pattern layer”) disposed on the first bottom gate electrode BG1, and a first gate electrode GE1 disposed on the first active layer ACT1. The buffer layer BFL may be disposed between the first bottom gate electrode BG1 and the first active layer ACT1. The first gate insulating layer GI1 may be disposed between the first active layer ACT1 and the first gate electrode GE1.

In an embodiment, the first transistor T1 may further include the first source electrode SE1 and a first drain electrode DE1 connected to different parts of the first active layer ACT1. In another example, the first transistor T1 may not include a separate source electrode and/or a separate drain electrode, and a first source region SR1 and/or a first drain region DR1 of the first active layer ACT1 may be connected to another circuit element, wire, and/or conductive pattern layer to function as the source electrode and/or the drain electrode of the first transistor T1.

The first bottom gate electrode BG1 may be provided in (or formed as) the first conductive layer CDL1 on the substrate SUB. In an embodiment, the first conductive layer CDL1 may be disposed between the substrate SUB and the buffer layer BFL. For example, the first conductive layer CDL1 may be disposed on the barrier layer BRL and covered by the buffer layer BFL.

The first bottom gate electrode BG1 may overlap the first active layer ACT1. For example, the first bottom gate electrode BG1 may be disposed under the first active layer ACT1 to overlap at least a first channel region CH1. The first bottom gate electrode BG1 and the first active layer ACT1 may be spaced apart from each other with the buffer layer BFL interposed between the first bottom gate electrode BG1 and the first active layer ACT1. The first bottom gate electrode BG1 may face the first gate electrode GE1 with the first active layer ACT1 interposed between the first bottom gate electrode BG1 and the first gate electrode GE1. In an embodiment, the first bottom gate electrode BG1 may be connected (e.g., electrically connected) to the first source electrode SE1, and may be utilized (or functioned) as a back-gate electrode that adjusts the characteristics of the first transistor T1.

The first active layer ACT1 may be included or provided in a semiconductor layer SCL on the substrate SUB. In an embodiment, the semiconductor layer SCL may be disposed on the buffer layer BFL, and may be covered by the gate insulating layer GI and the interlayer insulating layer ILD.

The first active layer ACT1 may include a first portion ACT11 positioned at the center portion, and a second portion ACT12 and a third portion ACT13 spaced apart from each other with the first portion ACT11 interposed between the second portion ACT12 and the third portion ACT13. For example, the second portion ACT12 and the third portion ACT13 of the first active layer ACT1 may be positioned on (or positioned at or around) sides (e.g., opposite sides) of the first portion ACT11.

At least a part of the first active layer ACT1 including the first portion ACT11 may overlap the first bottom gate electrode BG1. The first portion ACT11 of the first active layer ACT1 may include the first channel region CH1. In an embodiment, the entire first portion ACT11 of the first active layer ACT1 may be the first channel region CH1. The first channel region CH1 may be a region that maintains semiconductor characteristics without becoming conductive.

The first active layer ACT1 may include the first source region SR1 and the first drain region DR1 positioned at the second portion ACT12 and the third portion ACT13, respectively. For example, the second portion ACT12 of the first active layer ACT1 may include the first source region SR1, and the third portion ACT13 of the first active layer ACT1 may include the first drain region DR1. In an embodiment, the entire second portion ACT12 of the first active layer ACT1 may be the first source region SR1, and the entire third portion ACT13 of the first active layer ACT1 may be the first drain region DR1. The first source region SR1 may be positioned on (or positioned at or around) a side of the first channel region CH1, and the first drain region DR1 may be positioned on (or positioned at or around) another of the first channel region CH1. The first source region SR1 and the first drain region DR1 may be spaced apart from each other with the first channel region CH1 interposed between the first source region SR1 and the first drain region DR1. The first source region SR1 and the first drain region DR1, which are regions that have become conductive, may have a carrier concentration (for example, electron concentration) higher than that of the first channel region CH1.

The first gate insulating layer GI1 may be disposed on a part of the first active layer ACT1. For example, the first gate insulating layer GI1 may be disposed between the first active layer ACT1 and the first gate electrode GE1, and between the first active layer ACT1 and first dummy gate electrodes DG1.

In an embodiment, the first gate insulating layer GI1 may have a shape that is etched to cover only a part of the first active layer ACT1 and expose another part of the first active layer ACT1. For example, the first gate insulating layer GI1 may include an insulating pattern layer that is interposed between the first active layer ACT1 and the first gate electrode GE1 and covers at least the first portion ACT11 of the first active layer ACT1. For example, the first gate insulating layer GI1 may include an insulating pattern layer that is disposed under the first gate electrode GE1 and covers the first portion ACT11 of the first active layer ACT1 and a part of the second portion ACT12 and a part of the third portion ACT13 that are adjacent (e.g., directly adjacent) to the first portion ACT11. The first gate insulating layer GI1 may not be provided on another part of the second portion ACT12 and another part of the third portion ACT13 of the first active layer ACT1, and thus may expose another part of the second portion ACT12 and another part of the third portion ACT13 of the first active layer ACT1. The first gate insulating layer GI1 may further include at least one insulating pattern layer interposed between the first active layer ACT1 and at least one first dummy gate electrode DG1 disposed on the first active layer ACT1. For example, the first gate insulating layer GI1 may further include insulating pattern layers respectively disposed under the first dummy gate electrodes DG1 positioned on (or positioned at or around) sides (e.g., opposite sides) of the first gate electrode GE1.

In an embodiment, the insulating pattern layers disposed on the first active layer ACT1 may be separated from each other. However, embodiments are not limited thereto. For example, the first gate insulating layer GI1 may be formed of an integrated insulating pattern layer in plan view and may have a shape that is etched to include an opening corresponding to a part of the second portion ACT12 and an opening corresponding to a part of the third portion ACT13 of the first active layer ACT1.

Since the first gate insulating layer GI1 exposes a part of the second portion ACT12 and a part of the third portion ACT13 of the first active layer ACT1, the first source region SR1 and the first drain region DR1 may become appropriately and/or readily conductive in the manufacturing process of the display panel 110. For example, the first gate insulating layer GI1 may be formed by etching the gate insulating layer GI such that a part of the second portion ACT12 and a part of the third portion ACT13 of the first active layer ACT1 may be exposed, and the interlayer insulating layer ILD may be formed in a state where a part of the second portion ACT12 and a part of the third portion ACT13 of the first active layer ACT1 are exposed, so that the first source region SR1 and the first drain region DR1 may become appropriately and/or readily conductive without performing a separate doping process.

The first gate electrode GE1 and first dummy gate electrodes DG1 may be disposed on the first gate insulating layer GI1. The first gate electrode GE1 and the first dummy gate electrodes DG1 may be included or provided in a second conductive layer CDL2 on the substrate SUB. In an embodiment, the second conductive layer CDL2 may be disposed on the gate insulating layer GI, and may be covered by the interlayer insulating layer ILD.

The first gate electrode GE1 may be disposed on a portion of the first active layer ACT1 including the first portion ACT11. For example, the first gate electrode GE1 may be disposed on the first portion ACT11 of the first active layer ACT1 to overlap at least the first channel region CH1.

In an embodiment, the first gate electrode GE1 may also be disposed on a part of the second portion ACT12 and a part of the third portion ACT13 of the first active layer ACT1 to overlap a part of the first source region SR1 and a part of the first drain region DR1. For example, the first gate electrode GE1 may overlap the first source region SR1 and the first drain region DR1 by a section corresponding to (or having) a length ΔL1 in a part of the first source region SR1 and a part of the first drain region DR1 that are in contact with the first channel region CH1. The section corresponding to (or having) the length ΔL1 in each of the first source region SR1 and the first drain region DR1 may diffuse (extend) to a part of the region where oxygen vacancies that occur at a part (e.g., the second portion ACT12 and the third portion ACT13) of the first active layer ACT1 overlapping the first gate electrode GE1 and the first gate insulating layer GI1 during the manufacturing process of the display panel 110, and may correspond to the section where the first source region SR1 and the first drain region DR1 extend.

Although FIG. 6 shows an embodiment in which the first channel region CH1 overlaps each of the first source region SR1 and the first drain region DR1 by the section corresponding to (or having) the same length, embodiments are not limited thereto. Further, due to process variation or the like, the length and/or area of the section where the first channel region CH1 and the first source region SR1 overlap may be different from the length and/or area of the section where the first channel region CH1 and the first drain region DR1 overlap.

Accordingly, the first gate electrode GE1 may cover at least the first channel region CH1, and may overlap a part of the first source region SR1 and a part of the first drain region DR1 by the section corresponding to (or having) a first length (e.g., two times ΔL1) in the longitudinal direction of the first active layer ACT1. For example, each of end portions (e.g., opposite end portions) of the first gate electrode GE1 may overlap the first source region SR1 and the first drain region DR1 by the area corresponding to the section having the length ΔL1 of the first active layer ACT1.

At least one first dummy gate electrode DG1 separated (or spaced apart) from the first gate electrode GE1 may be disposed above at least one of the second portion ACT12 and the third portion ACT13 of the first active layer ACT1. In an embodiment, the first dummy gate electrodes DG1 may be disposed above each of the second portion ACT12 and the third portion ACT13 of the first active layer ACT1.

Since the first dummy gate electrodes DG1 (e.g., two first dummy gate electrodes DG1) spaced apart from the first gate electrode GE1 are disposed on (or disposed at or around) sides (e.g., opposite sides) of the first gate electrode GE1, oxygen vacancies that occur at a part of the first active layer ACT1, which is not covered by the first gate insulating layer GI1 and is exposed, may diffuse in directions (e.g., opposite directions) in the first active layer ACT1 during the manufacturing process of the display panel 110. For example, at a part of the first active layer ACT1 exposed in the region between the first gate electrode GE1 and the first dummy gate electrodes DG1, oxygen vacancies may occur in the oxide semiconductor forming the first active layer ACT1 due to an etching gas or the like in the patterning process of the first gate insulating layer GI1 or the like. The oxygen vacancies may diffuse to the region under the first gate electrode GE1 of the first active layer ACT1, and may also diffuse to the region under each of the first dummy gate electrodes DG1 of the first active layer ACT1. For example, by forming the first dummy gate electrodes DG1, the diffusion direction of the oxygen vacancies occurring at the first active layer ACT1 may be distributed. For example, since the first dummy gate electrodes DG1 spaced apart from the first gate electrode GE1 are disposed on (or disposed at or around) sides (e.g., opposite sides) of the first gate electrode GE1, hydrogen flowing into a part of the first active layer ACT1 that is not covered by the first gate insulating layer GI1 may diffuse in directions (e.g., opposite directions) in the first active layer ACT1 during the manufacturing process of the display panel 110.

Since the oxygen vacancies diffuse in directions (e.g., opposite directions) in the first active layer ACT1, it is possible to reduce the amount of diffusion of the oxygen vacancies diffused to a part of the first active layer ACT1 positioned under the first gate electrode GE1 and/or the length of the region where the oxygen vacancies diffuse under the first gate electrode GE1. Accordingly, the overlapping area between the first gate electrode GE1 and the first source and drain regions SR1 and DR1 may be reduced.

In case that the overlapping area between the first gate electrode GE1 and the first source and drain regions SR1 and DR1 is reduced, the magnitude (or value) of the parasitic capacitance (e.g., the capacitance formed between the first gate electrode GE1 and the first source and drain regions SR1 and DR1) formed in the first transistor T1 may be reduced. In an embodiment, the first transistor T1 may be a driving transistor for controlling the driving current Id flowing into (or toward) the light emitting element ED in response to the voltage applied to the first gate electrode GE1. By reducing or minimizing the magnitude (or value) of the parasitic capacitance formed in the first transistor T1, it is possible to prevent, reduce, or minimize characteristic changes and/or characteristic variation of the first transistor T1. Accordingly, it is possible to prevent, reduce, or minimize blurring of the image due to the luminance variation of the pixels PX, and to improve the image quality of the display device 100.

In an embodiment, each of the first dummy gate electrodes DG1 may have a length Ld1 that is less than or equal to the first length corresponding to two times ΔL1 in the longitudinal direction of the first active layer ACT1. Accordingly, a part of the first active layer ACT1 that overlaps each of the first dummy gate electrodes DG1 may become conductive by hydrogen and/or oxygen vacancies diffused from directions (e.g., opposite directions). Accordingly, the second portion ACT12 and the third portion ACT13 of the first active layer ACT1, including the region overlapping each of the first dummy gate electrodes DG1, may be regions that have become conductive to the first source and drain regions SR1 and DR1. For example, the second portion ACT12 and the third portion ACT13 of the first active layer ACT1 may exhibit electrical characteristics that are substantially the same as those of a conductor.

The semiconductor layer SCL including the first active layer ACT1, the gate insulating layer GI including the first gate insulating layer GI1, and the second conductive layer CDL2 including the first gate electrode GE1 and the first dummy gate electrodes DG1 may be covered by the interlayer insulating layer ILD. A third conductive layer CDL3 may be disposed on the interlayer insulating layer ILD.

The first source electrode SE1 and the first drain electrode DE1 may be included or provided in (or formed as) the third conductive layer CDL3. For example, the first source electrode SE1 and the first drain electrode DE1 may be disposed on the interlayer insulating layer ILD, and may be connected (e.g., electrically connected) to the first source region SR1 and the first drain region DR1, respectively.

In the embodiment of FIG. 6, the first transistor T1 of each pixel PX may be connected to the light emitting element ED of the corresponding pixel PX. For example, the first source electrode SE1 of each pixel PX may be connected (e.g., directly connected) to the first electrode ET1 of the light emitting element ED through at least one contact hole or via hole penetrating the passivation layer PSV.

However, embodiments are not limited thereto. For example, the panel circuit layer PCL may further include the fourth conductive layer disposed on the passivation layer PSV and the insulating layer covering the fourth conductive layer, and the first transistor T1 may be connected to the light emitting element ED through a bridge pattern layer included or provided in (or formed as) the fourth conductive layer.

The second transistor T2 may include the second bottom gate electrode BG2 disposed on the substrate SUB, a second active layer ACT2 (also referred to as “second active pattern layer”) disposed on the second bottom gate electrode BG2, and a second gate electrode GE2 disposed on the second active layer ACT2. The buffer layer BFL may be disposed between the second bottom gate electrode BG2 and the second active layer ACT2. The second gate insulating layer GI2 may be disposed between the second active layer ACT2 and the second gate electrode GE2.

In an embodiment, the second transistor T2 may further include the second source electrode SE2 and the second drain electrode DE2 connected to different parts of the second active layer ACT2. In another example, the second transistor T2 may not include a separate source electrode and/or a separate drain electrode, and a second drain region DR2 and/or a second source region SR2 of the second active layer ACT2 may be connected to another circuit element, wire, and/or conductive pattern layer to function as a source electrode and/or drain electrode of the second transistor T2.

The second bottom gate electrode BG2 may be included or provided in (or formed as) the first conductive layer CDL1 on the substrate SUB. For example, the second bottom gate electrode BG2 may be included or provided in (or formed as) the first conductive layer CDL1 together with the first bottom gate electrode BG1.

The second bottom gate electrode BG2 may overlap the second active layer ACT2. For example, the second bottom gate electrode BG2 may be disposed under the second active layer ACT2 to overlap at least the second channel region CH2. The second bottom gate electrode BG2 and the second active layer ACT2 may be spaced apart from each other with the buffer layer BFL interposed between the second bottom gate electrode BG2 and the second active layer ACT2. The second bottom gate electrode BG2 may face the second gate electrode GE2 with the second active layer ACT2 interposed between the second bottom gate electrode BG2 and the second gate electrode GE2. In an embodiment, the second bottom gate electrode BG2 may be connected to the second gate electrode GE2 of the second transistor T2 and may be utilized (or functioned) as a back-gate electrode to adjust the characteristics of the second transistor T2.

The second active layer ACT2 may be included or provided in (or formed as) the semiconductor layer SCL on the substrate SUB. In an embodiment, the first active layer ACT1 and the second active layer ACT2 may be provided and/or disposed on the same layer (for example, the same semiconductor layer SCL) on the substrate SUB.

The second active layer ACT2 may include a first portion ACT21 positioned at the center portion, and a second portion ACT22 and a third portion ACT23 spaced apart from each other with the first portion ACT21 interposed between the second portion ACT22 and the third portion ACT23. For example, the second portion ACT22 and the third portion ACT23 of the second active layer ACT2 may be positioned on (or positioned at or around) sides (e.g., opposite sides) of the first portion ACT21 of the second active layer ACT2.

At least a part of the second active layer ACT2 including the first portion ACT21 may overlap the second bottom gate electrode BG2. The first portion ACT21 of the second active layer ACT2 may include the second channel region CH2. In an embodiment, the entire first portion ACT21 of the second active layer ACT2 may be the second channel region CH2. The second channel region CH2 may be a region that maintains semiconductor characteristics without becoming conductive.

The second active layer ACT2 may include the second source region SR2 and the second drain region DR2 that are respectively positioned at the second portion ACT22 and the third portion ACT23. For example, the second portion ACT22 of the second active layer ACT2 may include the second source region SR2, and the third portion ACT23 of the second active layer ACT2 may include the second drain region DR2. In an embodiment, the entire second portion ACT22 of the second active layer ACT2 may be the second source region SR2, and the entire third portion ACT23 of the second active layer ACT2 may be the second drain region DR2. The second source region SR2 may be positioned on (or positioned at or around) a side of the second channel region CH2, and the second drain region DR2 may be positioned on (or positioned at or around) another side of the second channel region CH2. The second source region SR2 and the second drain region DR2 may be spaced apart from each other with the second channel region CH2 interposed between the second source region SR2 and the second drain region DR2. The second source region SR2 and the second drain region DR2, which are regions that have become conductive, may have a carrier concentration (for example, electron concentration) higher than that of the second channel region CH2.

The second gate insulating layer GI2 may be disposed on a part of the second active layer ACT2. For example, the second gate insulating layer GI2 may be disposed between the second active layer ACT2 and the second gate electrode GE2, and between the second active layer ACT2 and second dummy gate electrodes DG2.

In an embodiment, the second gate insulating layer GI2 may have a shape that is etched to cover only a part of the second active layer ACT2 and expose another part of the second active layer ACT2. For example, the second gate insulating layer GI2 may include an insulating pattern layer that is interposed between the second active layer ACT2 and the second gate electrode GE2 and covers at least the first portion ACT21 of the second active layer ACT2. For example, the second gate insulating layer GI2 may include an insulating pattern layer that is disposed under the second gate electrode GE2, and covers the first portion ACT21 of the second active layer ACT2 and a part of the second portion ACT22 and a part of the third portion ACT23 that are adjacent (e.g., directly adjacent) to the first portion ACT21. The second gate insulating layer GI2 may not be provided on another part of the second portion ACT22 and another part of the third portion ACT23 of the second active layer ACT2, and thus may expose another part of the second portion ACT22 and another part of the third portion ACT23 of the second active layer ACT2. The second gate insulating layer GI2 may include at least one insulating pattern layer interposed between the second active layer ACT2 and at least one second dummy gate electrode DG2 disposed on the second active layer ACT2. For example, the second gate insulating layer GI2 may further include insulating pattern layers respectively disposed under the second dummy gate electrodes DG2 positioned on sides (e.g., opposite sides) of the second gate electrode GE2. In an embodiment, the insulating pattern layers disposed on the second active layer ACT2 may be separated from each other, but embodiments are not limited thereto.

Since the second gate insulating layer GI2 exposes a part of the second portion ACT22 and a part of the third portion ACT23 of the second active layer ACT2, the second source region SR2 and the second drain region DR2 may become appropriately and/or readily conductive during the manufacturing process of the display panel 110. For example, the second gate insulating layer GI2 may be formed by etching the gate insulating layer GI such that a part of the second portion ACT22 and a part of the third portion ACT23 of the second active layer ACT2 may be exposed, and the interlayer insulating layer ILD may be formed in a state where a part of the second portion ACT22 and a part of the third portion ACT23 of the second active layer ACT2 are exposed, so that the second source region SR2 and the second drain region DR2 may become appropriately and/or readily conductive without performing a separate doping process.

The second gate electrode GE2 and the second dummy gate electrodes DG2 may be disposed on the second gate insulating layer GI2. The second gate electrode GE2 and the second dummy gate electrodes DG2 may be included or provided in (or formed as) the second conductive layer CDL2 on the substrate SUB.

The second gate electrode GE2 may be disposed on a portion of the second active layer ACT2 including the first portion ACT21. For example, the second gate electrode GE2 may be disposed on the first portion ACT21 of the second active layer ACT2 to overlap at least the second channel region CH2.

In an embodiment, the second gate electrode GE2 may also be disposed on a part of the second portion ACT22 and a part of the third portion ACT23 of the second active layer ACT2 to overlap a part of the second source region SR2 and a part of the second drain region DR2. For example, the second gate electrode GE2 may overlap the second source region SR2 and the second drain region DR2 by a section corresponding to (or having) a length ΔL2 in a part of the second source region SR2 and a part of the second drain region DR2 that are in contact with the second channel region CH2. The section corresponding to (or having) the length ΔL2 in each of the second source region SR2 and the second drain region DR2 may diffuse (or extend) to a part of the region where oxygen vacancies that occur at a part (e.g., the second portion ACT22 and the third portion ACT23) of the second active layer ACT2 overlaps the second gate electrode GE2 and the second gate insulating layer GI2 during the manufacturing process of the display panel 110, and may correspond to the section where the second source region SR2 and the second drain region DR2 extend.

Although FIG. 6 shows an embodiment in which the second channel region CH2 overlaps each of the second source region SR2 and the second drain region DR2 by the section corresponding to (or having) the same length, embodiments are not limited to thereto. Further, due to process variation or the like, the length and/or area of the section where the second channel region CH2 and the second source region SR2 overlap may be different from the length and/or area of the section where the second channel region CH2 and the second drain region DR2 overlap.

Accordingly, the second gate electrode GE2 may cover at least the second channel region CH2, and may overlap a part of the second source region SR2 and a part of the second drain region DR2 by the section corresponding to (or having) a second length (e.g., two times ΔL2) in the longitudinal direction of the second active layer ACT2. For example, each of end portions (e.g., opposite end portions) of the second gate electrode GE2 may overlap the second source region SR2 and the second drain region DR2 by the area corresponding to the section of the length ΔL2 of the second active layer ACT2. In an embodiment, the first length and the second length (or ΔL1 and ΔL2) may be substantially the same as each other, but embodiments are not limited thereto.

At least one second dummy gate electrode DG2 separated from the second gate electrode GE2 may be disposed above at least one of the second portion ACT22 and the third portion ACT23 of the second active layer ACT2. In an embodiment, the second dummy gate electrodes DG2 may be disposed above each of the second portion ACT22 and the third portion ACT23 of the second active layer ACT2.

Since the second dummy gate electrodes DG2 (e.g., two second dummy gate electrodes DG2) spaced apart from the second gate electrode GE2 are disposed on (or positioned at or around) sides (e.g., opposite sides) of the second gate electrode GE2, oxygen vacancies that occur on a part of the second active layer ACT2 that is not covered by the second gate insulating layer GI2 may diffuse in directions (e.g., opposite directions) in the second active layer ACT2 during the manufacturing process of the display panel 110. For example, oxygen vacancies may occur in the oxide semiconductor forming the second active layer ACT2 in the patterning process of the second gate insulating layer GI2. The oxygen vacancies may diffuse to the region under the second gate electrode GE2 of the second active layer ACT2, and may also diffuse to the region under each of the second dummy gate electrodes DG2 of the second active layer ACT2. For example, by forming the second dummy gate electrodes DG2, the diffusion direction of the oxygen vacancies occurring at the second active layer ACT2 may be distributed. For example, since the second dummy gate electrodes DG2 spaced apart from the second gate electrode GE2 are disposed on (or disposed at or around) sides (e.g., opposite sides) of the second gate electrode GE2, hydrogen flowing into a part of the second active layer ACT2 that is not covered by the second gate insulating layer GI2 may diffuse in directions (e.g., opposite directions) in the second active layer ACT2 during the manufacturing process of the display panel 110.

Since the oxygen vacancies diffuse in directions (e.g., opposite directions) in the second active layer ACT2, it is possible to reduce the amount of diffusion of the oxygen vacancies diffused to a part of the second active layer ACT2 positioned under the second gate electrode GE2 and/or the length of the region where the oxygen vacancies diffuse under the second gate electrode GE2. Accordingly, the overlapping area between the second gate electrode GE2 and the second source and drain regions SR2 and DR2 may be reduced.

In case that the overlapping area between the second gate electrode GE2 and the second source and drain regions SR2 and DR2 is reduced, the magnitude (or value) of the parasitic capacitance (e.g., the capacitance formed between the second gate electrode GE2 and the second source and drain regions SR2 and DR2) formed in the second transistor T2 may be reduced. In an embodiment, the second transistor T2 may be electrically connected to the first gate electrode GE1. For example, the second source region SR2 and/or the second source electrode SE2 of the second transistor T2 may be electrically connected to the first gate electrode GE1. By reducing or minimizing the magnitude (or value) of the parasitic capacitance formed in the second transistor T2, the voltage variation of the first node N1 connected to the first gate electrode GE1 may be prevented, reduced, or minimized. Accordingly, it is possible to prevent, reduce, or minimize blurring of the image due to the luminance variation of the pixels PX, and to improve the image quality of the display device 100. In an embodiment, the second transistor T2 may be a switching transistor connected to the first driver 120 through a gate line GL (e.g., the first gate line GWL). By reducing or minimizing the magnitude (or value) of the parasitic capacitance formed in the second transistor T2, the load formed in the output terminal of the first driver 120 may be reduced. Accordingly, the output characteristics of the first driver 120 may be improved. In an embodiment, at least one dummy gate electrode may also be disposed in at least one other pixel transistor Tpx connected to the first node N1, similarly to the third transistor T3. Accordingly, it is possible to prevent, reduce, or minimize the voltage variation of the first node N1, and to reduce the load formed in the output terminal of the first driver 120.

In an embodiment, each of the second dummy gate electrodes DG2 may have a length Ld2 that is less than or equal to the second length corresponding to two times ΔL2 in the longitudinal direction of the second active layer ACT2. Accordingly, a part of the second active layer ACT2 that overlaps each of the second dummy gate electrodes DG2 may become electrically conductive by hydrogen and/or oxygen vacancies diffused from directions (e.g., opposite directions). Accordingly, the second portion ACT22 and the third portion ACT23 of the second active layer ACT2, including the region overlapping each of the second dummy gate electrodes DG2, may be regions that have become conductive to the second source and drain regions SR2 and DR2. For example, the second portion ACT22 and the third portion ACT23 of the second active layer ACT2 may exhibit electrical characteristics that are substantially the same as those of a conductor.

The second source electrode SE2 and the second drain electrode DE2 may be included or provided in (or formed as) the third conductive layer CDL3. For example, the second source electrode SE2 and the second drain electrode DE2 may be disposed on the interlayer insulating layer ILD, and may be connected (e.g., electrically connected) to the second source region SR2 and the second drain region DR2, respectively.

The pixel transistors Tpx, including the first transistor T1 and the second transistor T2 may be covered by the passivation layer PSV.

The respective electrodes, conductive pattern layers, and/or wires included or provided in the conductive layers of the panel circuit layer PCL may include at least one conductive material, and may each have a single layer structure or a multilayer structure. For example, the electrodes, the conductive pattern layers, and/or the wires included or provided in each of the first conductive layer CDL1, the second conductive layer CDL2, and the third conductive layer CDL3 may include at least one of copper (Cu), titanium (Ti), molybdenum (Mo), aluminum (Al), chromium (Cr), gold (Au), silver (Ag), platinum (Pt), palladium (Pd), nickel (Ni), neodymium (Nd), iridium (Ir), tantalum (Ta), tungsten (W), magnesium (Mg), or another metal, an alloy thereof, or another conductive material, and may each have a single layer structure or a multilayer structure. In an embodiment, the electrodes, the conductive pattern layers, and/or the wires disposed on the same conductive layer may be simultaneously formed of the same conductive material.

In an embodiment, the active layers (e.g., the first active layer ACT1 and the second active layer ACT2) included or provided in (or formed as) the semiconductor layer SCL may include an oxide semiconductor. For example, the active layers included or provided in (or formed as) the semiconductor layer SCL may include at least one of indium (In), gallium (Ga), zinc (Zn), or tin (Sn). For example, each of the first active layer ACT1 and the second active layer ACT2 may include at least one of zinc oxide (ZnO), zinc-tin oxide (ZTO), indium-zinc oxide (IZO), indium oxide (InO), titanium oxide (TiO), indium-gallium oxide (IGO), indium-gallium-zinc oxide (IGZO), indium-gallium-tin oxide (IGTO), indium-zinc-tin oxide (IZTO), or indium-tin-gallium-zinc oxide (ITGZO), or another oxide semiconductor. The oxide semiconductor used to form the oxide transistors including the first transistor T1 and the second transistor T2 is not limited to the above-described materials, and may be variously changed according to embodiments.

In an embodiment, the active layers included or provided in (or formed as) the same semiconductor layer SCL may include the same oxide semiconductor. For example, the first active layer ACT1 and the second active layer ACT2 may be formed simultaneously of the same oxide semiconductor.

The light emitting element layer LEL may be disposed on the panel circuit layer PCL, and may be positioned in the display area DA. For example, the light emitting element layer LEL may be disposed on the panel circuit layer PCL in the display area DA.

The light emitting element layer LEL may include the light emitting elements ED of the pixels PX. For example, the light emitting element layer LEL may include a pixel defining layer PDL (also referred to as “bank”) that partitions the emission areas of the pixels PX and the light emitting element ED positioned in each emission area. In an embodiment, the light emitting element layer LEL may further include a spacer SPC disposed on a part of the pixel defining layer PDL.

Each light emitting element ED may include the first electrode ET1 connected to at least one pixel transistor Tpx (for example, the first transistor T1) included in the corresponding pixel PX, and a light emitting layer EML and a second electrode ET2 that are sequentially disposed on the first electrode ET1. In an embodiment, the light emitting element ED may further include a first intermediate layer (e.g., a hole layer including a hole transport layer) interposed between the first electrode ET1 and the light emitting layer EML, and a second intermediate layer (e.g., an electron layer including an electron transport layer) interposed between the light emitting layer EML and the second electrode ET2.

The first electrode ET1 of the light emitting element ED may be disposed on the panel circuit layer PCL to correspond to (or to overlap) each emission area. The first electrode ET1 may include a conductive material. In an embodiment, the first electrode ET1 may include a metallic material having high reflectivity. For example, the first electrode ET1 may have a single layer structure of molybdenum (Mo), titanium (Ti), copper (Cu) or aluminum (Al), or may have a multi-layer structure (e.g., ITO/Mg, ITO/MgF, ITO/Ag, and ITO/Ag/ITO) including indium-tin-oxide (ITO), indium-zinc-oxide (IZO), zinc oxide (ZnO), indium oxide (In₂O₃) and silver (Ag), magnesium (Mg), aluminum (Al), platinum (Pt), lead (Pb), gold (Au), or nickel (Ni).

The light emitting layer EML of the light emitting element ED may include a high molecular material or a low molecular material. Light emitted from the light emitting layer EML may be used to image display. In an embodiment, the light emitting layer EML may be provided for each pixel PX, and the light emitting layer EML of each pixel PX may emit visible light of a color corresponding to the corresponding pixel PX. In another embodiment, the light emitting layer EML may be a common layer shared by the pixels PX of different colors, and a wavelength conversion layer and/or color filters corresponding to the color (or wavelength band) of light to be emitted from each pixel PX may be arranged in the emission areas of at least some of the pixels PX.

The second electrode ET2 of the light emitting element ED may include a conductive material. In an embodiment, the second electrode ET2 may be a common layer formed across the entire display area DA to cover the light emitting layer EML and the pixel defining layer PDL. In an embodiment, the second electrode ET2 may be formed of a transparent conductive material (TCO) such as ITO, IZO, ZnO, or ITZO capable of transmitting light or a semi-transmissive conductive material such as magnesium (Mg), silver (Ag), or an alloy of magnesium (Mg) and silver (Ag).

The pixel defining layer PDL may have an opening corresponding to (or overlapping) each emission area and may surround the emission area. For example, the pixel defining layer PDL may be formed to cover an edge portion of the first electrode ET1 of the light emitting element ED and may include an opening exposing the remaining portion of the first electrode ET1. A region where the exposed first electrode ET1 and the light emitting layer EML overlap may be defined as the emission area of each pixel PX.

In an embodiment, the pixel defining layer PDL may include at least one organic insulating layer including an organic insulating material. For example, the pixel defining layer PDL may include acrylic resin, epoxy resin, phenolic resin, polyamide resin, polyimide resin, unsaturated polyester resin, polyphenylene ether resin, polyphenylenesulfide resin and benzocyclobutene (BCB) or other organic insulating materials.

The spacer SPC may be disposed on a part of the pixel defining layer PDL. The spacer SPC may include at least one organic insulating layer including an organic insulating material. The spacer SPC and the pixel defining layer PDL may include the same material as each other. In another example, the spacer SPC may include a different material from the pixel defining layer PDL. In an embodiment, the pixel defining layer PDL and the spacer SPC may be sequentially formed by separate mask processes. In another embodiment, the pixel defining layer PDL and the spacer SPC may be an integrated pattern layer formed simultaneously using a halftone mask.

The encapsulation layer ENL may be disposed on the light emitting element layer LEL. The encapsulation layer ENL may cover the light emitting element layer LEL in the display area DA and may extend to the non-display area NDA to be in contact with the panel circuit layer PCL. For example, the encapsulation layer ENL may be disposed in the display area DA to cover the light emitting element layer LEL, and the end portion of the encapsulation layer ENL may be positioned in a portion of the non-display area NDA adjacent to the display area DA. The encapsulation layer ENL may prevent the permeation of oxygen or moisture into the light emitting element layer LEL, and may reduce electrical and/or physical impacts to the panel circuit layer PCL and the light emitting element layer LEL.

In an embodiment, the encapsulation layer ENL may have a multilayer structure including a first encapsulation layer ENL1, a second encapsulation layer ENL2, and a third encapsulation layer ENL3 sequentially disposed on the light emitting element layer LEL. Each of the first encapsulation layer ENL1 and the third encapsulation layer ENL3 may be an inorganic encapsulation layer including an inorganic material. The second encapsulation layer ENL2 may be an organic encapsulation layer including an organic material. The structure and/or material of the encapsulation layer ENL may be changed according to embodiments.

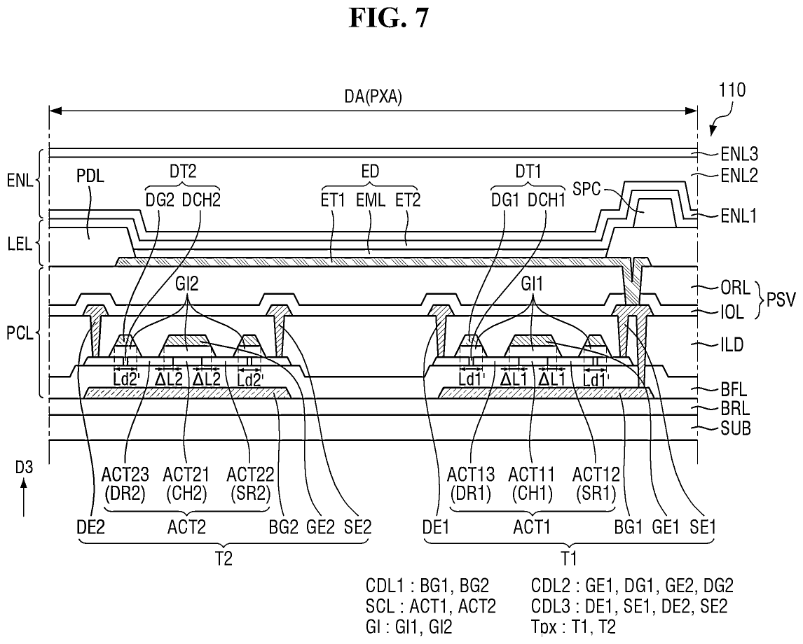

FIG. 7 is a schematic cross-sectional view illustrating the display panel 110 according to an embodiment. For example, FIG. 7 shows an embodiment that is different from the embodiment of FIG. 6 in relation to the lengths of the first and second dummy gate electrodes DG1 and DG2. In describing the following embodiments, redundant descriptions of components substantially identical or similar to those of at least an embodiment described above will be omitted for descriptive convenience.

Referring to FIG. 7 in addition to FIGS. 1 to 6, at least one first dummy gate electrode DG1 may have a length Ld1′ longer than the first length (e.g., two times ΔL1) in the longitudinal direction of the first active layer ACT1. Accordingly, the first active layer ACT1 may include at least one first dummy channel region DCH1 that is positioned in at least one of the second portion ACT12 or the third portion ACT13 and overlaps at least one first dummy gate electrode DG1.

For example, each of the first dummy gate electrodes DG1 positioned on (or positioned at or around) sides (e.g., opposite sides) of the first gate electrode GE1 may have the length Ld1′ longer than the first length (e.g., two times ΔL1) in the longitudinal direction of the first active layer ACT1. Accordingly, the first dummy channel region DCH1 may be formed under each of the first dummy gate electrodes DG1. For example, the first dummy channel region DCH1 may have a length corresponding to the value obtained by subtracting the first length (e.g., two times ΔL1) from the length Ld1′ of each of the first dummy gate electrodes DG1.

In embodiments, the second portion ACT12 and the third portion ACT13 of the first active layer ACT1 may refer to portions positioned on (or positioned at or around) different sides of the first portion ACT11. For example, the second portion ACT12 of the first active layer ACT1 may include at least the first source region SR1. Further, in case that the first dummy channel region DCH1 is formed under the first dummy gate electrode DG1 disposed on the second portion ACT12 of the first active layer ACT1, the second portion ACT12 of the first active layer ACT1 may include the first dummy channel region DCH1 and the regions (e.g., the first source region SR1 of the first transistor T1, or the source and drain regions of the first dummy transistor DT1) that have become conductive on sides (e.g., opposite sides) of the first dummy channel region DCH1. For example, the third portion ACT13 of the first active layer ACT1 may include at least the first drain region DR1. Further, in case that the first dummy channel region DCH1 is formed under the first dummy gate electrode DG1 disposed on the third portion ACT13 of the first active layer ACT1, the third portion ACT13 of the first active layer ACT1 may include the first dummy channel region DCH1 and the regions (e.g., the first drain region DR1 of the first transistor T1, or the source and drain regions of the first dummy transistor DT1) that have become conductive on sides (e.g., opposite sides) of the first dummy channel region DCH1.

Each first dummy gate electrode DG1 may cover each first dummy channel region DCH1, and may overlap a part of the first source region SR1 or a part of the first drain region DR1 around the first dummy channel region DCH1. For example, the first dummy gate electrode DG1 disposed on the second portion ACT12 of the first active layer ACT1 may cover the first dummy channel region DCH1 positioned at the second portion ACT12 of the first active layer ACT1, and may overlap a part of the first source region SR1 adjacent to the first dummy channel region DCH1. The first dummy gate electrode DG1 disposed on the third portion ACT13 of the first active layer ACT1 may cover the first dummy channel region DCH1 positioned at the third portion ACT13 of the first active layer ACT1, and may overlap a part of the first drain region DR1 adjacent to the first dummy channel region DCH1.

In an embodiment, each first dummy channel region DCH1 may have a short channel whose length falls within a threshold voltage roll-off region of the first dummy transistor DT1 including the first dummy channel region DCH1 and each first dummy gate electrode DG1. For example, each first dummy channel region DCH1 may have a short channel such that the first dummy transistor DT1 may operate in the threshold voltage roll-off region thereof. For example, the length Ld1′ of each of the first dummy gate electrodes DG1 may be smaller than or equal to the sum of a sub-threshold channel length of the first dummy transistor DT1 and the first length (e.g., two times ΔL1). Accordingly, each first dummy channel region DCH1 may have a length smaller than or equal to the sub-threshold voltage channel length of the first dummy transistor DT1. In an embodiment, each first dummy gate electrode DG1 may have a length smaller than that of the gate electrode GE of each of the pixel transistors Tpx provided in each pixel PX. Accordingly, each first dummy channel region DCH1 may have a length smaller than the length of the channel region of each of the pixel transistors Tpx.

Each first dummy transistor DT1 may substantially operate as a conductor due to a short-channel effect. For example, each first dummy transistor DT1 may operate as a wire.

For example, at least one second dummy gate electrode DG2 may have a length Ld2′ longer than the second length (e.g., two times ΔL2) in the longitudinal direction of the second active layer ACT2. Accordingly, the second active layer ACT2 may include at least one second dummy channel region DCH2 that is positioned in at least one of the second portion ACT22 or the third portion ACT23 and overlaps at least one second dummy gate electrode DG2.

For example, each of the second dummy gate electrodes DG2 positioned on sides (e.g., opposite sides) of the second gate electrode GE2 may have the length Ld2′ longer than the second length (e.g., two times ΔL2) in the longitudinal direction of the second active layer ACT2. Accordingly, the second dummy channel region DCH2 may be formed under each of the second dummy gate electrodes DG2. For example, the second dummy channel region DCH2 may have a length corresponding to the value obtained by subtracting the second length (e.g., two times ΔL2) from the length Ld2′ of each of the second dummy gate electrodes DG2.

Each second dummy gate electrode DG2 may cover each second dummy channel region DCH2, and may overlap a part of the second source region SR2 or a part of the second drain region DR2 around the second dummy channel region DCH2. For example, the second dummy gate electrode DG2 disposed on the second portion ACT22 of the second active layer ACT2 may cover the second dummy channel region DCH2 positioned at the second portion ACT22 of the second active layer ACT2, and may overlap a part of the second source region SR2 adjacent to the second dummy channel region DCH2. The second dummy gate electrode DG2 disposed on the third portion ACT23 of the second active layer ACT2 may cover the second dummy channel region DCH2 positioned at the third portion ACT23 of the second active layer ACT2, and may overlap a part of the second drain region DR2 adjacent to the second dummy channel region DCH2.

In an embodiment, each second dummy channel region DCH2 may have a short channel whose length falls within a threshold voltage roll-off region of the second dummy transistor DT2 including the second dummy channel region DCH2 and each second dummy gate electrode DG2. For example, each second dummy channel region DCH2 may have a short channel such that the second dummy transistor DT2 may operate in the threshold voltage roll-off region thereof. For example, the length Ld2′ of each of the second dummy gate electrodes DG2 may be less than or equal to the sum of the sub-threshold voltage channel length of the second dummy transistor DT2 and the second length (e.g., two times ΔL2). Accordingly, each second dummy channel region DCH2 may have a length less than or equal to the sub-threshold voltage channel length of the second dummy transistor DT2. In an embodiment, each second dummy gate electrode DG2 may have a length smaller than that of the gate electrode GE of each of the pixel transistors Tpx provided in each pixel PX. Accordingly, each second dummy channel region DCH2 may have a length smaller than that of the length of the channel region of each of the pixel transistors Tpx provided in each pixel PX.

Each second dummy transistor DT2 may substantially operate as a conductor due to the short channel effect. For example, each second dummy transistor DT2 may operate as a wire.

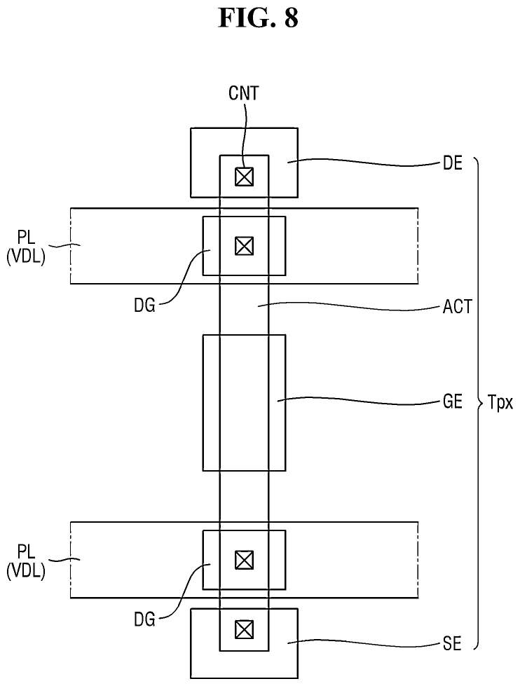

FIG. 8 is a schematic plan view showing the pixel transistor Tpx and the dummy gate electrode DG according to an embodiment. For example, FIG. 8 shows an additional embodiment of the embodiment of FIG. 5 in relation to the dummy gate electrode DG.

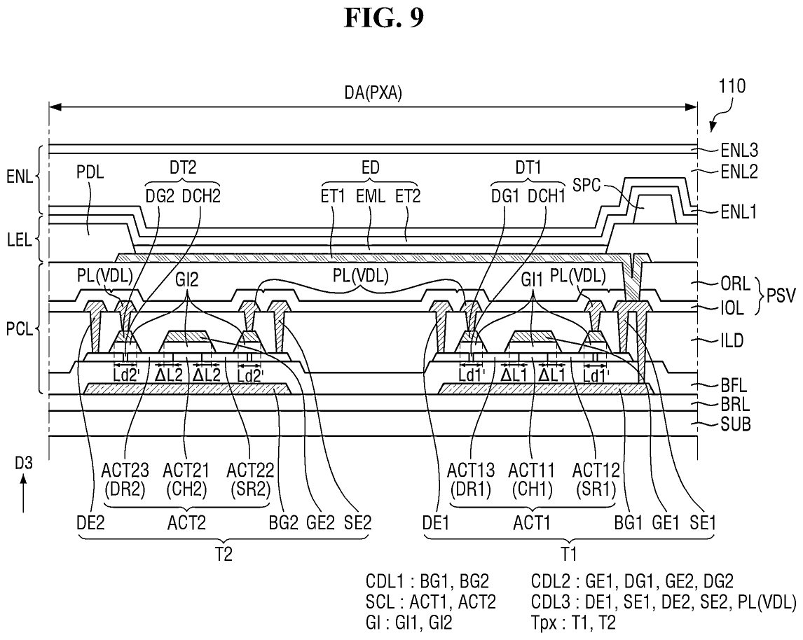

FIG. 9 is a schematic cross-sectional view illustrating the display panel 110 according to an embodiment. For example, FIG. 9 shows an additional embodiment of the embodiments of FIGS. 6 and 7 in relation to the first and second dummy gate electrodes DG1 and DG2.

Referring to FIGS. 8 and 9 in addition to FIGS. 1 to 7, the display panel 110 may include a power line PL connected to each dummy gate electrode DG and to which the gate-on voltage of each pixel transistor Tpx is applied. In an embodiment, the power line PL may be included or provided in (or formed as) the third conductive layer CDL3, but embodiments are not limited thereto. The location, shape, and/or cross-sectional structure of the power line PL may be variously changed according to embodiments.

In an embodiment, the power line PL may be the first power line VDL to which the first pixel voltage ELVDD is applied, and the dummy gate electrodes DG formed in the pixel PX may be connected to the same first power line VDL. For example, the dummy gate electrodes DG formed in the pixel PX, including the first dummy gate electrodes DG1 and the second dummy gate electrodes DG2, may be commonly connected to the first power line VDL (or sub-wires of the first power line VDL). However, embodiments are not limited thereto. For example, the power line PL connected to each dummy gate electrode DG may be variously changed according to embodiments.

Since each dummy gate electrode DG is connected to the power line PL, the gate-on voltage may be applied to each dummy gate electrode DG. Accordingly, the dummy transistors (e.g., the dummy transistors including the first dummy transistors DT1 and the second dummy transistors DT2) formed in the pixel PX may maintain a turn-on state for a period in which the display panel 110 is driven.

For example, although each first dummy gate electrode DG1 has the length Ld1′ longer than the first length corresponding to two times ΔL1, the gate-on voltage may be applied to each first dummy gate electrode DG1 during the period in which the display device 100 is driven and, accordingly, each first dummy transistor DT1 may maintain a turned-on state. For example, each first dummy transistor DT1 may operate as a wire.

For example, although each second dummy gate electrode DG2 has the length Ld2′ longer than the second length corresponding to two times ΔL2, the gate-on voltage may be applied to each second dummy gate electrode DG2 during the period in which the display device 100 is driven. Accordingly, each second dummy transistor DT2 may operate as a wire while maintaining the turn-on state.

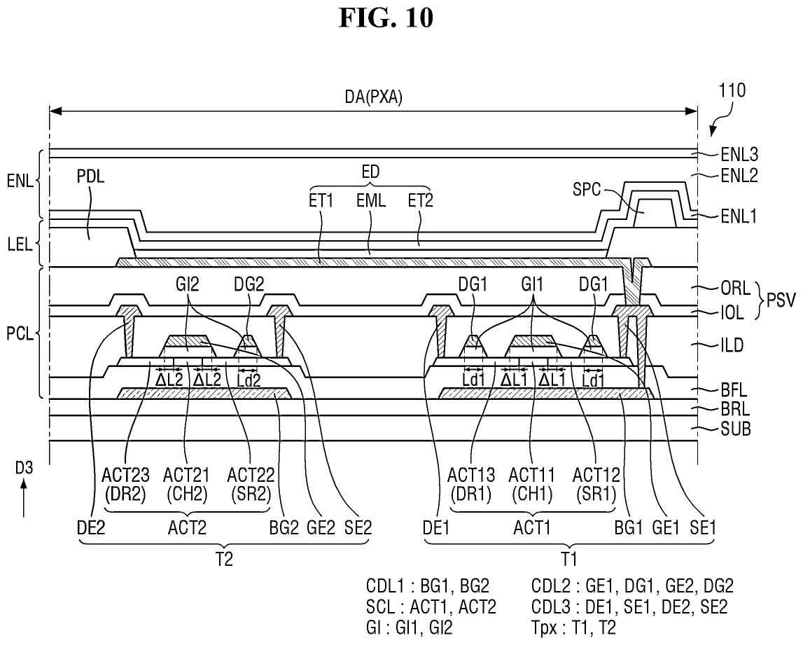

FIG. 10 is a schematic cross-sectional view illustrating the display panel 110 according to an embodiment. For example, FIG. 10 shows an embodiment that is different from the embodiments of FIGS. 6 to 9 in relation to the second dummy gate electrode DG2. For example, FIG. 10 shows a modified embodiment of the embodiment of FIG. 6 in relation to the second dummy gate electrode DG2.

Referring to FIG. 10 in addition to FIGS. 1 to 9, the second dummy gate electrode DG2 may be disposed on (or disposed at or around) only one side of the second gate electrode GE2. For example, the pixel PX may include a single second dummy gate electrode DG2 disposed only on the second portion ACT22 of the second active layer ACT2, and the second dummy gate electrode DG2 may not be disposed on the third portion ACT23 of the second active layer ACT2. The second portion ACT22 of the second active layer ACT2 may be a portion including the second source region SR2 connected (e.g., electrically connected) to the first gate electrode GE1.

Since the second dummy gate electrode DG2 is disposed on the second portion ACT22 of the second active layer ACT2, the magnitude (or value) of the parasitic capacitance formed between the second source region SR2 and the second gate electrode GE2 may be reduced. Accordingly, the image quality of the display device 100 may be improved by preventing, reducing, or minimizing voltage variation of the first node N1 connected to the first gate electrode GE1.

Since the second dummy gate electrode DG2 is not disposed on the third portion ACT23 of the second active layer ACT2, the size of the second transistor T2 (e.g., the length of the second active layer ACT2) may be reduced. Accordingly, the pixel area PXA may be utilized more efficiently.

In an embodiment, a single dummy gate electrode may be formed only at the portion connected to the first node N1 in at least one other pixel transistor Tpx connected to the first node N1, similarly to the third transistor T3. Accordingly, the area occupied by the pixel transistors Tpx may be reduced while preventing, reducing, or minimizing voltage variation of the first node N1.

Although FIGS. 6 to 10 show the embodiments in which at least one dummy gate electrode DG is disposed on the active layer ACT of each of the first transistor T1 that is the driving transistor of the pixel PX, and at least one switching transistor (e.g., the second transistor T2), the embodiments are not limited thereto. In another embodiment, at least one first dummy gate electrode DG1 (e.g., two first dummy gate electrodes DG1 positioned on (or positioned at or around) sides (e.g., opposite sides) of the first gate electrode GE1) may be provided only on the first active layer ACT1 of the first transistor T1, and the dummy gate electrode DG may not be disposed on the active layers ACT of the other pixel transistors Tpx (e.g., switching transistors). For example, the dummy gate electrode DG may be selectively disposed only in some pixel transistors Tpx in consideration of the operating characteristics of the pixel transistors Tpx and the area of the pixel area PXA. In another example, at least one dummy gate electrode DG may be disposed in each of all the pixel transistors Tpx to reduce changes and/or variation of the operating characteristics due to a parasitic capacitance. For example, the dummy gate electrode DG may be selectively formed in each pixel transistor Tpx in consideration of the area of the pixel area PXA and the operating characteristics of the pixel PX to be ensured.

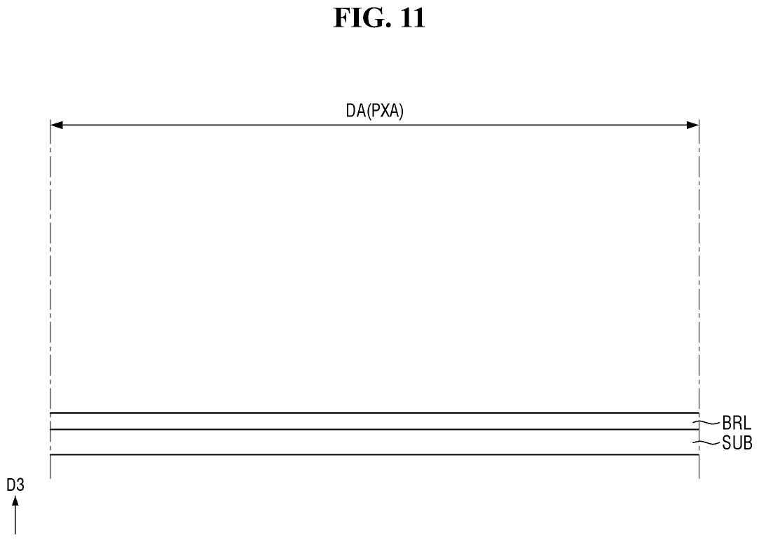

FIGS. 11, 12, 13, 14, 15, 16, 17 and 18 are schematic cross-sectional views illustrating a method of manufacturing the display device 100 according to an embodiment. For example, FIGS. 11 to 18 sequentially show steps of forming the pixel transistors Tpx on the substrate SUB among the steps of manufacturing the display panel 110 of FIG. 6. In an embodiment, the driver transistors provided in the first driver 120 may be formed simultaneously with the pixel transistors Tpx in a substantially same or similar manner as the pixel transistors Tpx.

Referring to FIG. 11 in addition to FIGS. 1 to 10, the substrate SUB including at least the display area DA may be prepared. The display area DA may include the pixel area PXA.

In an embodiment, the barrier layer BRL may be formed on the substrate SUB. The barrier layer BRL may be formed by a film forming process (e.g., deposition process) of an insulating layer using at least one insulating material (e.g., an inorganic insulating material) described above. Materials and/or methods for forming the barrier layer BRL may be variously changed according to embodiments.

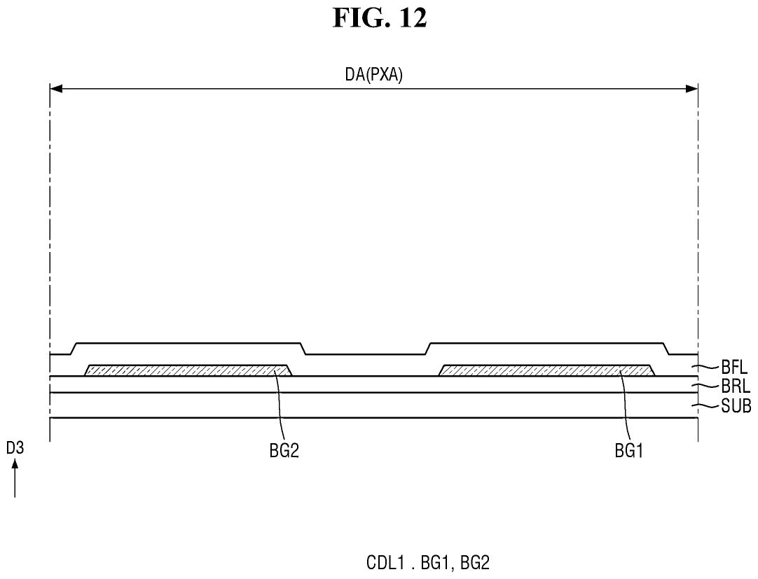

Referring to FIG. 12 in addition to FIGS. 1 to 11, the first conductive layer CDL1 including the bottom gate electrodes BG of the pixel transistors Tpx may be formed on the substrate SUB. For example, the first conductive layer CDL1 including the first bottom gate electrode BG1 and the second bottom gate electrode BG2 may be formed on the barrier layer BRL on the substrate SUB. The first bottom gate electrode BG1 and the second bottom gate electrode BG2 may be formed in each of the pixel areas PXA.

The first bottom gate electrode BG1 and the second bottom gate electrode BG2 may be formed by a film forming process (for example, a deposition process) of a conductive layer using at least one conductive material described above and a patterning process (for example, an etching process using a mask) of the conductive layer. Materials and/or methods for forming the first bottom gate electrode BG1 and the second bottom gate electrode BG2 may be variously changed according to embodiments.

Thereafter, the buffer layer BFL covering the first conductive layer CDL1 may be formed on the substrate SUB. The buffer layer BFL may be formed by a film forming process of an insulating layer using at least one insulating material (e.g., an inorganic insulating material) described above. Materials and/or methods for forming the buffer layer BFL may be variously changed according to embodiments.

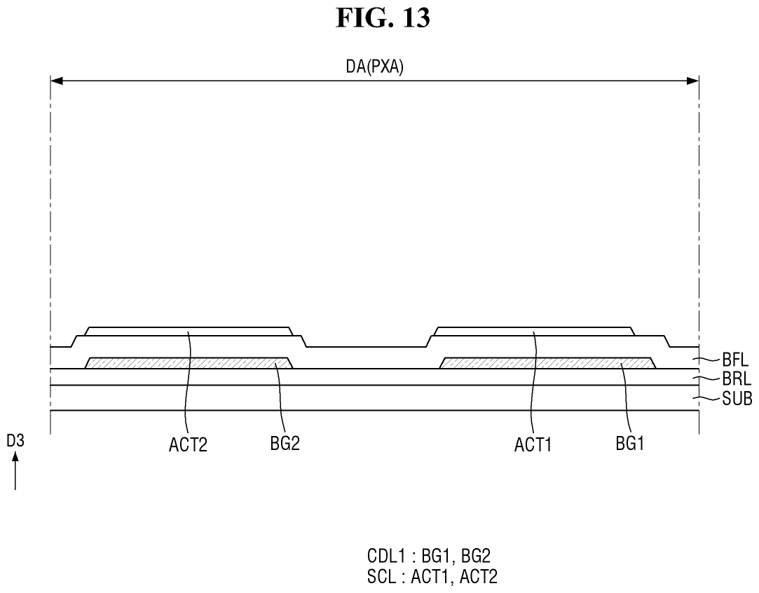

Referring to FIG. 13 in addition to FIGS. 1 to 12, the semiconductor layer SCL including the active layers ACT of the pixel transistors Tpx may be formed on the buffer layer BFL. For example, the first active layer ACT1, the second active layer ACT2 and the like may be formed in each of the pixel areas PXA. The first active layer ACT1 may be formed to overlap at least a part of the first bottom gate electrode BG1, and the second active layer ACT2 may be formed to overlap at least a part of the second bottom gate electrode BG2.

In an embodiment, the active layers ACT provided in (or formed as) the same semiconductor layer SCL may be formed simultaneously of the same oxide semiconductor. For example, the first active layer ACT1 and the second active layer ACT2 may be formed simultaneously of the same oxide semiconductor. For example, the first active layer ACT1, the second active layer ACT2 and the like may be formed in the pixel area PXA through the film forming process and patterning process of the oxide semiconductor layer using at least one oxide semiconductor described above.

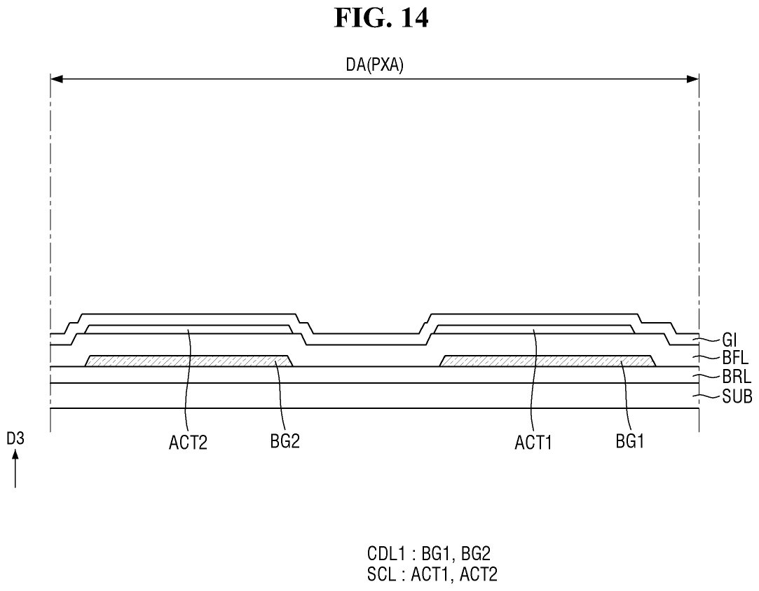

Referring to FIG. 14 in addition to FIGS. 1 to 13, the gate insulating layer GI may be formed to cover the semiconductor layer SCL. For example, the gate insulating layer GI covering the active layers (e.g., the first active layer ACT1 and the second active layer ACT2) provided in (or formed as) the semiconductor layer SCL may be formed on the substrate SUB.

The gate insulating layer GI may be formed entirely on the substrate SUB provided with the first and second active layers ACT1 and ACT2. For example, after the gate insulating layer GI is formed on the substrate SUB on which the semiconductor layer SCL is formed by a film forming process of an insulating layer using at least one insulating material (e.g., an inorganic insulating material) described above, a subsequent process such as heat treatment (e.g., annealing) or the like may be performed. Materials and/or methods for forming the gate insulating layer GI may be variously changed according to embodiments.

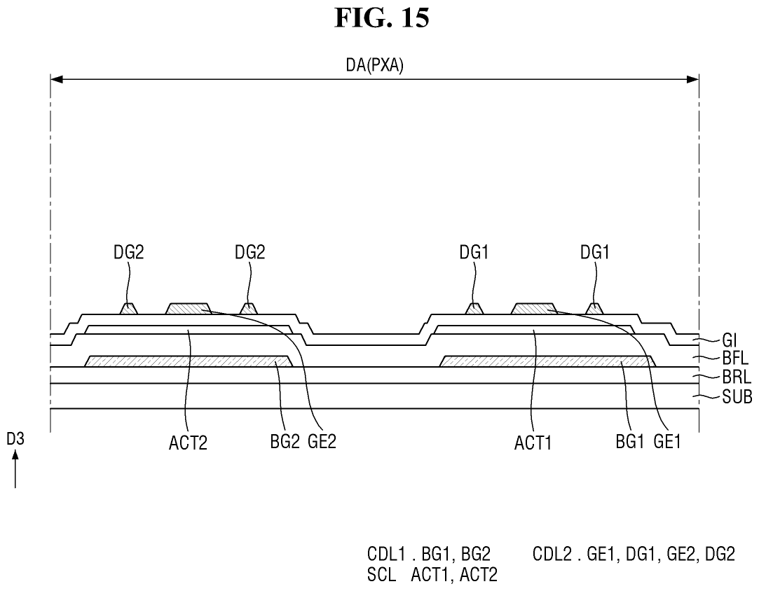

Referring to FIG. 15 in addition to FIGS. 1 to 14, the second conductive layer CDL2 may be formed on the gate insulating layer GI. The second conductive layer CDL2 may include the gate electrodes GE of the pixel transistors Tpx, including the first gate electrode GE1 and the second gate electrode GE2, and the dummy gate electrode DG disposed on the active layer ACT of at least one pixel transistor Tpx. On the active layer ACT where the dummy gate electrode DG is disposed, the gate electrode GE and at least one dummy gate electrode DG may be formed separately from each other with overlapping different parts of the active layer ACT. For example, the gate electrodes GE including the first gate electrode GE1 and the second gate electrode GE2, at least one first dummy gate electrode DG1 disposed on the first active layer ACT1 and separated from the first gate electrode GE1, and at least one second dummy gate electrode DG2 disposed on the second active layer ACT2 and separated from the second gate electrode GE2 may be formed in each pixel area PXA.

The gate electrodes GE and the dummy gate electrodes DG may be formed by a film forming process (e.g., a deposition process) of a conductive layer using at least one conductive material described above and a patterning process (e.g., an etching process using a mask) of the conductive layer. Materials and/or methods for forming the gate electrodes GE and the dummy gate electrodes DG may be variously changed according to embodiments.

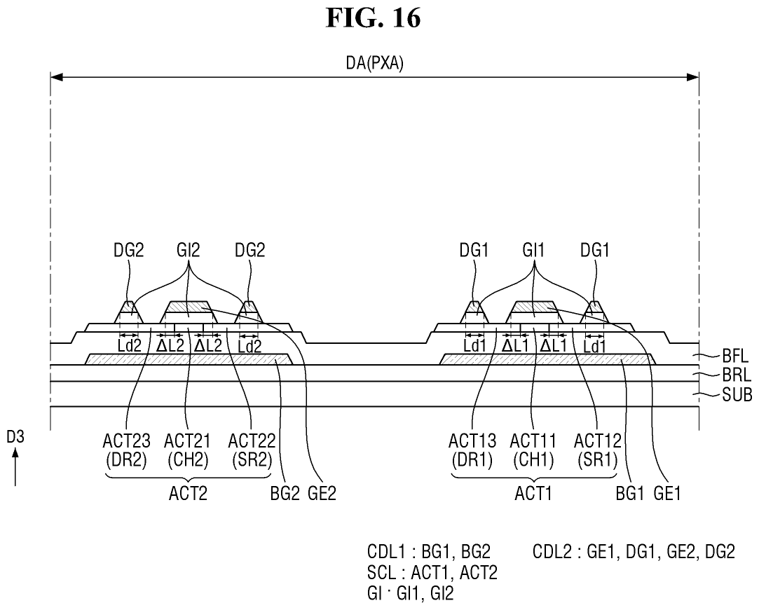

Referring to FIG. 16 in addition to FIGS. 1 to 15, the gate insulating layer GI may be etched to form the first gate insulating layer GI1 and the second gate insulating layer GI2. For example, by etching the gate insulating layer GI, the insulating pattern layers may be formed under the gate electrodes GE including the first and second gate electrodes GE1 and GE2 and the dummy gate electrodes DG including the first and second dummy gate electrodes DG1 and DG2, and a part of each of the active layers ACT may be exposed in the region that does not overlap the gate electrodes GE and the dummy gate electrodes DG.

In an embodiment, the gate insulating layer GI may be etched with utilizing a mask used for patterning the gate electrodes GE and the dummy gate electrodes DG or utilizing the gate electrodes GE and the dummy gate electrodes DG as a mask. Accordingly, the insulating pattern layers corresponding to the shapes and sizes of the gate electrodes GE and the dummy gate electrodes DG may be formed under the gate electrodes GE and the dummy gate electrodes DG.

In the process of forming the first gate insulating layer GI1 and the second gate insulating layer GI2 by etching the gate insulating layer GI, the properties of the active layers ACT may be changed such that the active layers ACT may have different characteristics at different parts. Accordingly, the active layers ACT may be divided into a plurality of regions (e.g., a channel region, a source region, and a drain region) having different characteristics.

For example, at a part that does not overlap the first gate electrode GE1 and the first dummy gate electrodes DG1, oxygen may be released from the oxide semiconductor of the first active layer ACT1 by an etching gas or the like, and oxygen vacancies may occur. Accordingly, the first active layer ACT1 may be divided into a plurality of regions (e.g., the first channel region CH1, the first drain region DR1, and the first source region SR1) having different characteristics. In an embodiment, oxygen vacancies may occur at a part of the first active layer ACT1 that is not covered by the first gate insulating layer GI1, and may diffuse to a part of the region overlapping the first gate electrode GE1, the first dummy gate electrodes DG1 and/or the first gate insulating layer GI1. In an embodiment, in case that each first dummy gate electrode DG1 has the length Ld1 less than or equal to the first length corresponding to two times ΔL1, oxygen vacancies may diffuse to the entire region overlapping the first dummy gate electrode DG1 of the first active layer ACT1.

For example, at a part that does not overlap the second gate electrode GE2 and the second dummy gate electrodes DG2, oxygen vacancies may occur in the second active layer ACT2. Accordingly, the second active layer ACT2 may be divided into a plurality of regions (e.g., the second channel region CH2, the second drain region DR2, and the second source region SR2) having different characteristics. In an embodiment, oxygen vacancies may occur at a part of the second active layer ACT2 that is not covered by the second gate insulating layer GI2, and may diffuse to a part of the region overlapping the second gate electrode GE2, and the second dummy gate electrodes DG2, and/or the second active layer ACT2. In an embodiment, in case that each second dummy gate electrode DG2 has the length Ld2 less than or equal to the second length corresponding to two times ΔL2, oxygen vacancies may diffuse to the entire region overlapping the second dummy gate electrode DG2 of the second active layer ACT2.

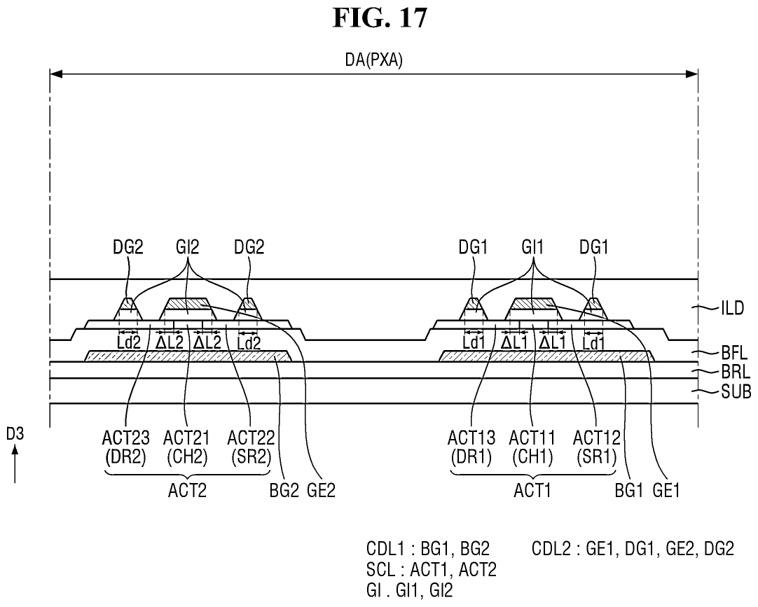

Referring to FIG. 17 in addition to FIGS. 1 to 16, the active layers ACT (e.g., the first and second active layers ACT1 and ACT2) included or provided in (or formed as) the semiconductor layer SCL, the insulating pattern layers (e.g., the first and second gate insulating layers GI1 and GI2) included or provided in the gate insulating layer GI, the gate electrodes GE (e.g., the first and second gate electrodes GE1 and GE2) included or provided in (or formed as) the second conductive layer CDL2, and the interlayer insulating layer ILD covering the dummy gate electrodes DG (e.g., the first and second dummy gate electrodes DG1 and DG2) may be formed. The interlayer insulating layer ILD may be formed by the film forming process of an insulating layer by using at least one insulating material (e.g., an inorganic insulating material) described above. In an embodiment, after forming the interlayer insulating layer ILD, a subsequent process such as heat treatment may be performed. Materials and/or methods for forming the interlayer insulating layer ILD may be variously changed according to embodiments.

In the process of forming the interlayer insulating layer ILD, hydrogen may flow into the active layers ACT of the semiconductor layer SCL. For example, hydrogen may flow into a part of the active layers ACT that is not covered by the gate electrodes GE and/or the dummy gate electrodes DG. Accordingly, the source region and the drain region of each of the active layers ACT may become conductive to have appropriate conductivity.

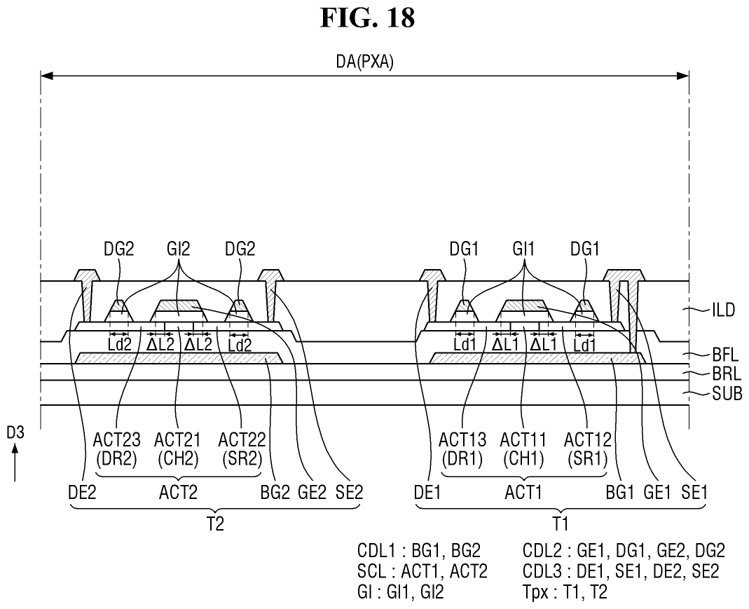

Referring to FIG. 18 in addition to FIGS. 1 to 17, the third conductive layer CDL3 including the source electrodes SE and the drain electrodes DE may be formed on the interlayer insulating layer ILD. For example, the first drain electrode DE1, the first source electrode SE1, the second source electrode SE2, and the second drain electrode DE2 may be formed on the interlayer insulating layer ILD. In an embodiment, at least one of the first drain region DR1, the first source region SR1, the second source region SR2, or the second drain region DR2 may replace at least one of the first drain electrode DE1, the first source electrode SE1, the second source electrode SE2, or the second drain electrode DE2, at least one of the first drain electrode DE1, the first source electrode SE1, the second source electrode SE2, or the second drain electrode DE2 may not be formed.

The first source electrode SE1 and the first drain electrode DE1 may be formed to be connected to different parts of the first active layer ACT1. For example, the first source electrode SE1 may be connected to the first source region SR1, and the first drain electrode DE1 may be connected to the first drain region DR1. The second source electrode SE2 and the second drain electrode DE2 may be formed to be connected to different parts of the second active layer ACT2. For example, the second source electrode SE2 may be connected to the second source region SR2, and the second drain electrode DE2 may be connected to the second drain region DR2. For example, prior to the formation of the first drain electrode DE1, the first source electrode SE1, the second source electrode SE2, and the second drain electrode DE2, contact holes may be formed in the interlayer insulating layer ILD.

Through the above-described process, pixel transistors Tpx including the first transistor T1 and the second transistor T2 and the dummy gate electrodes DG may be formed in the display area DA. In an embodiment, elements provided on the same conductive layer or the same semiconductor layer SCL in the display panel 110 may be formed simultaneously.

After the pixel transistors Tpx are formed, a process of forming the passivation layer PSV shown in FIG. 6 or the like may be performed. The passivation layer PSV may cover the pixel transistors Tpx. Accordingly, the panel circuit layer PCL of the display panel 110 may be formed.

In an embodiment, in case that the display panel 110 includes the light emitting element layer LEL and the encapsulation layer ENL disposed on the panel circuit layer PCL, the light emitting element layer LEL and the encapsulation layer ENL may be sequentially formed on the panel circuit layer PCL. By the above-described processes, the display panel 110 and the display device 100 including the same according to the embodiments may be manufactured.

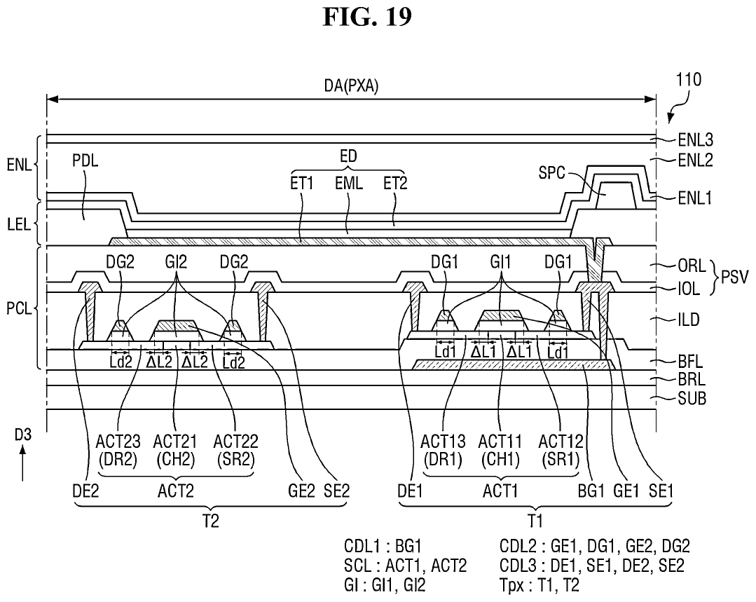

FIG. 19 is a schematic cross-sectional view illustrating the display panel 110 according to an embodiment. For example, FIG. 19 shows an embodiment that is different from the embodiment of FIG. 6 in relation to the bottom gate electrode BG.

Although FIG. 19 shows a modified embodiment of the embodiment of FIG. 6, the embodiment of FIG. 19 may also be applied to other embodiments. For example, the embodiment of FIG. 19 may also be applied to at least one of the embodiments of FIGS. 7, 9, and 10.

Referring to FIG. 19 in addition to FIGS. 1 to 18, each pixel transistor Tpx or each switching transistor provided in the pixel PX may or may not include each bottom gate electrode BG. In an embodiment, at least one pixel transistor Tpx (e.g., a driving transistor) provided in the pixel PX may include the bottom gate electrode BG, and at least one other pixel transistor Tpx (e.g., at least one switching transistor) provided in the pixel PX may not include the bottom gate electrode BG. For example, the first transistor T1 may include the first bottom gate electrode BG1, and the second transistor T2 may not include the bottom gate electrode BG (e.g., the second bottom gate electrode BG2 of FIG. 6). As described above, the structure of the pixel PX in relation to the bottom gate electrode BG may be variously changed according to embodiments.

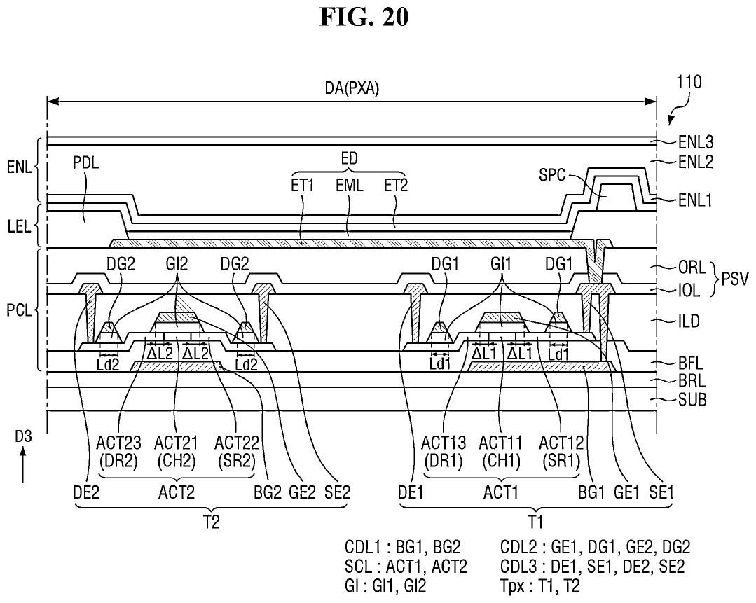

FIG. 20 is a schematic cross-sectional view illustrating the display panel 110 according to an embodiment. For example, FIG. 20 shows an embodiment that is different from the embodiment of FIG. 6 in relation to the bottom gate electrode BG.

Although FIG. 20 shows a modified embodiment of the embodiment of FIG. 6, the embodiment of FIG. 20 may also be applied to other embodiments. For example, the embodiment of FIG. 20 may also be applied to at least one of the embodiments of FIGS. 7, 9, 10, and 19.

Referring to FIG. 20 in addition to FIGS. 1 to 19, the bottom gate electrode BG provided in the pixel transistor Tpx may not overlap at least one dummy gate electrode DG provided in the pixel transistor Tpx. For example, the second bottom gate electrode BG2 provided in the second transistor T2 may not overlap the second dummy gate electrodes DG2 provided in the second transistor T2. For example, the second bottom gate electrode BG2 may be disposed under the second active layer ACT2 to overlap the second gate electrode GE2, and may have a reduced width so as not to overlap the second dummy gate electrodes DG2. However, the embodiments are not limited thereto. For example, the second bottom gate electrode BG2 may overlap one of the second dummy gate electrodes DG2 and may not overlap another one of the second dummy gate electrodes DG2.

For example, the first bottom gate electrode BG1 provided in the first transistor T1 may not overlap at least one first dummy gate electrode DG1 provided in the first transistor T1. For example, the first bottom gate electrode BG1 may be disposed under the first active layer ACT1 to overlap the first gate electrode GE1, and may not overlap the first dummy gate electrode DG1 adjacent to the first drain electrode DE1. In an embodiment, the first bottom gate electrode BG1 may overlap the first dummy gate electrode DG1 adjacent to the first source electrode SE1. However, the embodiments are not limited thereto. For example, the first bottom gate electrode BG1 may extend to the position under the first source electrode SE1 with bypassing the region where the first dummy gate electrode DG1 adjacent to the first source electrode SE1 is disposed.

For example, the shape, size, and/or location of the bottom gate electrode BG provided in each pixel transistor Tpx may be variously changed according to embodiments.

In concluding the detailed description, those skilled in the art will appreciate that many variations and modifications can be made to the embodiments without substantially departing from the principles of the invention. Therefore, the disclosed embodiments of the invention are used in a generic and descriptive sense only and not for purposes of limitation.

What is claimed is:

1. A display device comprising:
a substrate;
a first transistor comprising:
a first active layer disposed on the substrate and comprising:
a first portion comprising a first channel region, and
a second portion and a third portion spaced apart from each other with the first portion disposed between the second portion and the third portion, and a first gate electrode disposed on the first portion of the first active layer;
at least one first dummy gate electrode disposed on a part of at least one of the second portion or the third portion of the first active layer and spaced apart from the first gate electrode; and
a first gate insulating layer disposed between the first active layer and each of the first gate electrode and the at least one first dummy gate electrode.

2. The display device of claim 1, wherein the first gate insulating layer comprises a first insulating pattern layer disposed between the first active layer and the first gate electrode, and exposes a part of each of the second portion and the third portion of the first active layer.

3. The display device of claim 2, wherein the first gate insulating layer further comprises a second insulating pattern layer disposed between the at least one first dummy gate electrode and the first active layer.

4. The display device of claim 1, wherein
the first active layer further comprises:
a first source region disposed in the second portion and disposed at a side of the first channel region, and
a first drain region disposed in the third portion and disposed at another side of the first channel region, and
the first gate electrode covers at least the first channel region, and overlaps a part of the first source region and a part of the first drain region by a first length in a longitudinal direction of the first active layer.

5. The display device of claim 4, wherein the first dummy gate electrode has a length less than or equal to the first length in the longitudinal direction of the first active layer.

6. The display device of claim 4, wherein
the first dummy gate electrode has a length longer than the first length in the longitudinal direction of the first active layer, and
the first active layer further comprises at least one dummy channel region disposed in at least one of the second portion or the third portion and overlapping the first dummy gate electrode.

7. The display device of claim 6, wherein the first dummy gate electrode covers the dummy channel region, and overlaps a part of the first source region or a part of the first drain region around the dummy channel region.

8. The display device of claim 7, wherein the dummy channel region has a short channel such that a dummy transistor comprising the first dummy gate electrode and the dummy channel region operates in a threshold voltage roll-off region.

9. The display device of claim 7, further comprising:
a pixel comprising a plurality of pixel transistors comprising the first transistor,
wherein the dummy channel region has a length shorter than a length of a channel region of each of the plurality of pixel transistors.

10. The display device of claim 4, further comprising:
an interlayer insulating layer disposed on the substrate, and covering the first active layer, the first gate insulating layer, the first gate electrode and the first dummy gate electrode,
wherein the first transistor further comprises at least one of a first source electrode disposed on the interlayer insulating layer and electrically connected to the first source region, or a first drain electrode disposed on the interlayer insulating layer and electrically connected to the first drain region.

11. The display device of claim 1, further comprising:
a power line electrically connected to the first dummy gate electrode and to which a gate-on voltage of the first transistor is applied.

12. The display device of claim 1, further comprising:
a pixel comprising a pixel circuit comprising the first transistor and a light emitting element connected to the pixel circuit,
wherein the first transistor is a driving transistor which controls a driving current flowing through the light emitting element in response to a voltage applied to the first gate electrode.

13. The display device of claim 12, wherein
the at least one first dummy gate electrode comprises a plurality of first dummy gate electrodes, and
the plurality of first dummy gate electrodes are disposed at sides of the first gate electrode and disposed above each of the second portion and the third portion of the first active layer.

14. The display device of claim 12, wherein
the pixel circuit further comprises a second transistor electrically connected to the first gate electrode, and
the second transistor comprises:
a second active layer disposed on the substrate, and comprising:
a first portion comprising a second channel region,
a second portion disposed at a side of the second channel region and comprising a second source region, and
a third portion disposed at another side of the second channel region and comprising a second drain region; and
a second gate electrode disposed on the first portion of the second active layer.

15. The display device of claim 14, wherein the pixel further comprises:
at least one second dummy gate electrode disposed on a part of at least one of the second portion or the third portion of the second active layer, and spaced apart from the second gate electrode; and
a second gate insulating layer comprising insulating pattern layers disposed between the second active layer and each of the second gate electrode and the at least one second dummy gate electrode.

16. The display device of claim 15, wherein
the second gate insulating layer exposes a part of each of the second portion and the third portion of the second active layer, and
the second gate electrode covers at least the second channel region, and overlaps a part of each of the second source region and the second drain region around the second channel region.

17. The display device of claim 15, wherein
the at least one second dummy gate electrode comprises a plurality of second dummy gate electrodes, and
the plurality of second dummy gate electrodes are disposed at sides of the second gate electrode and disposed above each of the second portion and the third portion of the second active layer.

18. The display device of claim 15, wherein
the second source region is electrically connected to the first gate electrode, and
the pixel comprises a single second dummy gate electrode disposed only on the second portion of the second active layer.

19. The display device of claim 14, wherein the first active layer and the second active layer include an oxide semiconductor.

20. A method of manufacturing a display device, the method comprising:
forming an active layer including an oxide semiconductor on a substrate;
forming a gate insulating layer covering the active layer on the substrate;
forming, on the gate insulating layer, a gate electrode and at least one dummy gate electrode which overlap different parts of the active layer and are spaced apart from each other;
by etching the gate insulating layer, forming insulating pattern layers under each of the gate electrode and the at least one dummy gate electrode, and exposing a part of the active layer which does not overlap the gate electrode and the at least one dummy gate electrode; and
forming an interlayer insulating layer covering the active layer, the insulating pattern layers, the gate electrode and the at least one dummy gate electrode.
